(19) United States
(12) Patent Application Publication
(10) Pub. No.: US 2011/0141825 A1
(43) Pub. Date: Jun. 16, 2011

(54) SEMICONDUCTOR INTEGRATED CIRCUIT SYSTEM AND ELECTRONIC EQUIPMENT

(75) Inventors: Ichiro Hatanaka, Osaka (JP); Kenji Misumi, Kyoto (JP); Tomoyuki Aihara, Osaka (JP); Masanori Shirahama, Shiga (JP)

(73) Assignee: PANASONIC CORPORATION, Osaka (JP)

(21) Appl. No.: 13/036,327

(22) Filed: Feb. 28, 2011

Related U.S. Application Data
(63) Continuation of application No. PCT/JP2009/007057, filed on Dec. 21, 2009.

(30) Foreign Application Priority Data
Jun. 15, 2009 (JP) 2009-141912

(51) Int. Cl. G11C 7/00; G11C 5/14; G06F 1/04

(52) U.S. Cl. 365/189.07; 365/226; 327/291

(57) ABSTRACT

A semiconductor integrated circuit system comprises a semiconductor memory device including a memory cell array having a plurality of memory cells; a monitor circuit for monitoring characteristics of the memory cells; and a voltage output circuit connected to the semiconductor memory device to supply a power supply voltage to the semiconductor memory device; the voltage output circuit being configured to change an output voltage according to an output of the monitor circuit.

### CROSS-REFERENCE TO RELATED APPLICATION

This is a continuation application under 35 U.S.C 111(a) of pending prior International application No. PCT/JP2009/007057, filed on Dec. 21, 2009. The disclosure of Japanese Patent Application No. 2009-141912 filed on Jun. 15, 2009 including specification, drawings and claims is incorporated here in by reference in its entirety.

### BACKGROUND OF THE INVENTION

1. Field of the Invention

The present invention relates to a semiconductor integrated circuit system and electronic equipment including a semiconductor memory device.

2. Description of the Related Art

In a semiconductor integrated circuit system, a manufacturing variation in threshold voltages of transistors which are major constituents of the semiconductor integrated circuit system has been increasing because a manufacturing process for miniaturized constituents progresses. Since the variation in the threshold voltages of the transistors causes a problem that a proper characteristic or operation of the semiconductor integrated circuit system cannot be ensured, a method for solving this problem has been studied.

In recent years, the semiconductor integrated circuit system has a problem that a leak current of the transistors increases with a progress in the manufacturing process for miniaturized constituents. In addition, with a higher functionality of a system, a capacity of a semiconductor memory device mounted thereinto tends to increase, and therefore, in the semiconductor integrated circuit system, electric power consumption in a memory cell array of the mounted semiconductor memory device occupies a larger part of electric power consumption in an overall system. Under the circumstances, to achieve lower electric power consumption in the semiconductor integrated circuit system, it is essential that the electric power consumption in the memory cell array of the semiconductor memory device be reduced.

To solve problems that the manufacturing variation in the threshold voltages of the transistors increases and the leak current increases, International Publication No. 2003/094235 discloses a configuration for controlling a body bias which effectively reduces a stand-by current according to a manufacturing variation in threshold voltages of transistors, by noting a dependency of the stand-by current with respect to the threshold voltages of the transistors. To be specific, the threshold voltages of the transistors constituting a MOS circuit in a finish stage of manufacturing are monitored and a body bias voltage for minimizing a leak current in the MOS circuit is set according to a result of the monitoring.

If a bias state of the transistor of the memory cell is weaken, a data retaining ability of the memory cell is lost, so that stored data is erased. Therefore, a power supply voltage supplied to the semiconductor memory device is required to be set in a range which is not less than a voltage with which all of the memory cells constituting the memory cell array in the semiconductor memory device can retain data.

If the manufacturing variation in the threshold voltages of the transistors constituting the memory cells increases, an operation margin for a write operation or a read operation of the memory cells decreases, during a normal operation of the semiconductor memory device. To address such an increase in the variation in the threshold voltages of the transistors, an assist circuit is mounted. The assist circuit is adapted to regulate a power supply voltage supplied to the memory cells during the normal operation to increase the operation margin of the memory cells. A method in which a tester outside a semiconductor integrated circuit system monitors finish threshold voltages of transistors constituting the memory cells and an assist amount is set according to a result of the monitoring, is conventionally known.

### SUMMARY OF THE INVENTION

However, the conventional semiconductor integrated circuit system has the following problems. With an increase in a manufacturing variation in the threshold voltages of the transistors, an optimal body bias which can minimize a leak current is varied from chip to chip. For this reason, in a test step just after the manufacturing, the tester outside the semiconductor integrated circuit system detects finish threshold voltages of the transistors of the memory cells, and programs setting of an optimal body bias, according to a result of detection. Such a test step brings about an increase in a test cost. Since a characteristic of the transistors in the memory cell array could be degraded with time, it is difficult to attain a power supply voltage according to a characteristics of the memory cells, merely by setting the voltages based on the characteristics of the transistors obtained in the test step just after the manufacturing.

The present invention has been developed to solve the above described problem, and an object of the present invention is to provide a semiconductor integrated circuit system and electronic equipment including a semiconductor memory device, which are capable of supplying to memory cells constituting a memory cell array of the semiconductor memory device, a voltage which enables the semiconductor memory device to maintain a proper characteristic and operation during a long-time use, without increasing a test cost.

A semiconductor integrated circuit system of the present invention comprises a semiconductor memory device including a memory cell array having a plurality of memory cells; a monitor circuit for monitoring characteristics of the memory cells; and a voltage output circuit connected to the semiconductor memory device to supply a power supply voltage to the semiconductor memory device; the voltage output circuit being configured to change an output voltage according to an output of the monitor circuit.

In accordance with the semiconductor integrated circuit system having the above configuration, since the voltage output circuit changes the voltage supplied to the semiconductor memory device, according to the characteristics of the memory cells monitored by the monitor circuit, it is possible to supply a voltage which enables the semiconductor memory device to maintain a proper characteristic and operation, to the memory cells constituting the memory cell array of the semiconductor memory device, without increasing a test cost, even when there is a manufacturing variation in the threshold voltages of the transistors of the memory cells or degradation progressing over a long-time use. To be specific, since the output of the voltage output circuit which supplies a power supply voltage to the memory cell array is changed according to the characteristics of the memory cells monitored by the monitor circuit, in a stand-by mode of the semiconductor memory device, it is possible to supply a power supply voltage which allows the leak current characteristic and the data retaining characteristic of the memory cells to be satisfied well, without increasing a test cost, even when there is a manufacturing variation in the threshold voltages of the transistors of the memory cells or degradation progressing over a long-time use. Also, since the output of the voltage output circuit is changed according to the characteristics of the memory cells monitored by the monitor circuit, in a normal operation of the semiconductor memory device, it is possible to supply to the memory cells a voltage which can ensure a proper operation margin, without increasing a test cost, even when there is a manufacturing variation in the threshold voltages of the transistors of the memory cells or degradation progressing over a long-time use.

The voltage output circuit may include a first voltage output circuit and a second voltage output circuit, the first voltage output circuit or the second voltage output circuit is selectively connected to the semiconductor memory device, and the second voltage output circuit is configured to change the output voltage according to the output of the monitor circuit. In accordance with this configuration, since the first or second voltage output circuit for supplying the power supply voltage to the semiconductor memory device is selectively switched, the power supply voltage supplied to the semiconductor memory device can be switched between when the first voltage output circuit is connected to the semiconductor memory device and when the second voltage output circuit is connected to the semiconductor memory device. Since the second voltage output circuit, of the two voltage output circuits, is used to supply the power supply voltage in the stand-by mode of the semiconductor memory device and can change the power supply voltage according to the characteristics of the memory cells, it is possible to supply a power supply voltage which allows the leak current characteristic and the data retaining characteristic to be satisfied well, without affecting a write operation and a read operation to the memory cells.

The second voltage output circuit may include a variable resistor for dividing a voltage to be applied, according to the output of the monitor circuit, and is configured to change the output voltage according to the voltage dividing ratio of the variable resistor. Thereby, since the output voltage changes according to a voltage dividing ratio of the variable resistor, it is possible to change the power supply voltage supplied to the semiconductor memory device according to the output of the monitor circuit with high accuracy.

The semiconductor integrated circuit system may further comprises a power supply switching unit for switching the voltage output circuit to be connected to the semiconductor memory device between the first voltage output circuit and the second voltage output circuit, and the power supply switching unit may be configured to permit the power supply voltage to be supplied to the first voltage output circuit and inhibit the power supply voltage from being supplied to the second voltage output circuit in a first mode in which the first voltage output circuit is connected to the semiconductor memory device; and the power supply switching unit may be configured to permit the power supply voltage to be supplied to the second voltage output circuit and inhibit the power supply voltage from being supplied to the first voltage output circuit in a second mode in which the second voltage output circuit is connected to the semiconductor memory device. In this way, the power supply voltage is inhibited from being supplied to the voltage output circuit which is not connected to the semiconductor memory device, of the first and second voltage output circuits, and thereby electric power consumption can be lessened.

The output voltage of the second voltage output circuit may be set lower than the output voltage of the first voltage output circuit. In accordance with this configuration, since the output voltage of the second voltage output circuit which can change the output voltage is lower than the output voltage of the first voltage output circuit, it is possible to supply the power supply voltage which allows the leak current characteristic and the data retaining characteristic to be satisfied, to the semiconductor memory device, while achieving low electric power consumption, by connecting the second voltage output circuit to the semiconductor memory device in the stand-by mode of the semiconductor memory device.

The monitor circuit may include a memory cell array section including at least one memory cell having a configuration identical to a configuration of the memory cells included in the memory cell array of the semiconductor memory device and a resistor section having one end connected to an outside power supply and an opposite end connected to a power supply line in the memory cell array section, and is configured to output a voltage value at the opposite end side of the resistor section as the characteristics of the memory cells. In accordance with this configuration, since the resistor section is provided between the outside power supply and the power supply line of the memory cell array section, a voltage value of the resistor section at the power supply line side indicates a voltage value associated with a leak current in the memory cell array section of the monitor circuit. Since the voltage value associated with the leak current in the memory cell array section having the same configuration as the memory cell array of the semiconductor memory device is output as the characteristics of the memory cells of the semiconductor memory device, it is possible to monitor the leak current characteristic of the memory cell in the semiconductor memory device, with higher accuracy.

The semiconductor integrated circuit system may comprise a detecting circuit for digitizing the output of the monitor circuit; and the detecting circuit may include one or more comparators for comparing the output voltage of the monitor circuit to one or more reference voltages. Thereby, since the voltage value output from the monitor circuit is digitized by one or more comparators, the output voltage of the voltage output circuit can be regulated easily and in multi-levels.

The detecting circuit may include one or more holding circuits for holding output data of the one or more comparators; the comparator is configured to start outputting data in response to a predetermined first signal; and the holding circuit may be configured to, in response to a second signal, take in and hold output data from the comparator, at a time point when the holding circuit receives the second signal sent after a lapse of a predetermined time after the first signal is sent. In accordance with this configuration, since the power supply voltage supplied to the semiconductor memory device is changed based on the voltage value at the time point when the second signal is sent after a lapse of the predetermined time after the first signal is sent, among the voltage values output from the monitor circuit, the output of the monitor circuit in a state where the output characteristic of the monitor circuit is not stable yet just after the power is ON, etc, is not used as a reference for changing the power supply voltage supplied to the semiconductor memory device, thus allowing the power supply voltage to be supplied to the semiconductor memory device stably.

The second signal may be a signal generated from the first signal, and the detecting circuit may be configured such that the second signal reaches the holding circuit after a lapse of a predetermined time after the first signal reaches the comparator. Since the second signal is a signal generated from the first signal, a circuit configuration can be simplified.

The first signal may be input to the semiconductor memory device.

The semiconductor integrated circuit system may further comprise a monitor circuit control unit for switching a state of the memory cell constituting the memory cell array section of the monitor circuit between Low level and High level. Thereby, since the state of the memory cell in the memory cell array section of the monitor circuit is switched between Low level and High level according to the state of the memory cell in the semiconductor memory device, a characteristic change in the memory cell in the monitor circuit after a long-time use can be made closer to a characteristic change in the memory cells in the semiconductor memory device, and thus, the power supply voltage to be supplied can be regulated with high accuracy during a long-time use.

The monitor circuit control unit may be configured to switch the state of the memory cell constituting the memory cell array section of the monitor circuit between Low level and High level, in accordance with an input signal identical to an input signal to the semiconductor memory device. Since the state of memory cell in the memory cell array section is switched based on the input signal for switching the state of the memory cell of the semiconductor memory device, a characteristic change in the memory cell in the memory cell array section can be made closer to the characteristic change in the memory cells of the semiconductor memory device.

The input signal identical to the input signal to the semiconductor memory device may include a clock signal defining a clock frequency for controlling the semiconductor memory device and a chip enable signal for switching an operation mode of the memory cells of the semiconductor memory device; and the monitor circuit control unit may be configured to switch the state of the memory cell constituting the memory cell array section between Low level and High level, in synchronization with the clock signal and in accordance with the chip enable signal. Thereby, a characteristic change in the memory cells in the memory cell array section can be made closer to a characteristic change in the memory cells of the semiconductor memory device.

The voltage output circuit may include a first voltage output circuit and a second voltage output circuit, the first voltage output circuit or the second voltage output circuit is selectively connected to the semiconductor memory device, and the second voltage output circuit is configured to change the output voltage according to the output of the monitor circuit; the monitor circuit may include a switch element connected in parallel with the resistor section; and the switch element may be turned ON in a state where the semiconductor memory device is connected to the first voltage output circuit and is turned OFF in a state where the semiconductor memory device is connected to the second voltage output circuit. In accordance with this configuration, since the first voltage output circuit or the second voltage output circuit for supplying the power supply voltage to the semiconductor memory device is selectively switched, the power supply voltage supplied to the semiconductor memory device is switched between when the first voltage output circuit is connected to the semiconductor memory device and when the second voltage output circuit is connected to the semiconductor memory device. Since the second voltage output circuit of the two voltage output circuits, is used to supply the power supply voltage in the stand-by mode of the semiconductor memory device and thereby the second voltage output circuit can change the supplied power supply voltage according to the voltage value output from the memory circuit, in the stand-by mode, it is possible to supply the power supply voltage which allows the leak current characteristic and the data retaining characteristic to be satisfied well, without affecting a write operation and a read operation to the memory cells. In addition, since the outside power supply and the memory cell array section are short-circuited in a state where the first voltage output circuit which does not change the power supply voltage is connected to the semiconductor memory device, the voltage supplied to the memory cell in the memory cell array section can be made closer to the voltage supplied to the memory cell of the semiconductor memory device, and a characteristic change in the memory cells in the memory cell array section can be made closer to the characteristic change in the memory cells of the semiconductor memory device.

The semiconductor integrated circuit system may be configured to change the power supply voltage of the memory cell array of the semiconductor memory device according to the output of the monitor circuit in a write operation of the semiconductor memory device, and change a word line voltage of the memory cell array of the semiconductor memory device according to the output of the monitor circuit in a read operation of the semiconductor memory device. In accordance with this configuration, since the power supply voltage and the word line voltage supplied to the semiconductor memory device are changed, according to the output of the monitor circuit during a write operation and a read operation of the semiconductor memory device, it is possible to sufficiently ensure voltages required for the write operation and the read operation of the semiconductor memory device.

The semiconductor integrated circuit system may further comprises a write assist circuit for changing the power supply voltage of the memory cell array of the semiconductor memory device according to the output of the monitor circuit, in writing of the semiconductor memory device; and a read assist circuit for changing a power supply voltage of a word line driver for driving the word line voltage of the memory cell array of the semiconductor memory device, according to the output of the monitor circuit, in reading of the semiconductor memory device. In accordance with this configuration, the write assist circuit inputs to the memory cell array the voltage regulated according to the output of the monitor circuit as an auxiliary voltage, while the read assist circuit inputs to the memory cell array the voltage regulated according to the output of the monitor circuit as an auxiliary voltage. This makes it possible to easily carry out writing and reading of the semiconductor memory device according to a manufacturing variation.

An aspect of electronic equipment of the present invention, comprises the semiconductor integrated circuit system having the above configuration, a clock generating circuit for generating a clock signal defining a clock frequency for controlling the semiconductor integrated circuit system; and a controller for changing the clock frequency of the clock signal generated in the clock generating circuit, according to the output of the monitor circuit. In accordance with the electronic equipment having the above configuration, since the voltage output circuit changes the voltage supplied to the semiconductor memory device, according to the characteristics of the memory cells monitored by the monitor circuit, it is possible to supply a voltage which enables the semiconductor memory device to maintain a proper characteristic and operation, to the memory cells constituting the memory cell array of the semiconductor memory device, without increasing a test cost, even when there is a manufacturing variation in the threshold voltages of the transistors of the memory cells or degradation progressing over a long-time use. In addition, since the operational speed of the memory cell changes according to the characteristic change in the memory cell, the controller changes the clock frequency of the clock signal to address the change in the operational speed, and thus the memory cell of the semiconductor memory device can be made operative with an optimal clock frequency. As a result, a higher-speed operation of the electronic equipment is achieved.

Another aspect of electronic equipment of the present invention, comprises a semiconductor integrated circuit system including a semiconductor memory device including a memory cell array having a plurality of memory cells and a monitor circuit for monitoring characteristics of the memory cells; a voltage output circuit connected to the semiconductor memory device to supply a power supply voltage to the semiconductor memory device; and a controller for changing the output voltage of the voltage output circuit according to the output of the monitor circuit. In accordance with the electronic equipment having the above configuration, since the controller changes the voltage supplied from voltage output circuit to the semiconductor memory device, according to the characteristics of the memory cells monitored by the monitor circuit, it is possible to supply a voltage which enables the semiconductor memory device to maintain a proper characteristic and operation, to the memory cells constituting the memory cell array of the semiconductor memory device, even when there is a manufacturing variation in the threshold voltages of the transistors of the memory cells or degradation progressing over a long-time use.

Hereinafter, definition of terms used in claims and description will be explained.

The term “characteristic of memory cell” in claims and description means threshold voltages of the transistors of the memory cells or parameters which can be converted into the threshold voltages of transistors of the memory cells. Specifically, for example, a leak current of the memory cell array, its corresponding voltage value into which the leak current is converted, etc.

The present invention is configured as described above and achieves an advantage that it is possible to supply a voltage which enables the semiconductor memory device to maintain a proper characteristic and operation, to the memory cells constituting the memory cell array of the semiconductor memory device, without increasing a test cost, even when there is a manufacturing variation in the threshold voltages of the transistors of the memory cells or degradation progressing over a long-time use. As a result, the present invention achieves an advantage that, for example, in a stand-by mode of the semiconductor memory device, the output of the voltage output circuit for supplying the power supply voltage to the memory cell array is changed according to the characteristics of the memory cells monitored by the monitor circuit, and thus, it is possible to supply a power supply voltage which allows the leak current characteristic and the data retaining characteristic of the memory cells to be satisfied well, without increasing a test cost, even when there is a manufacturing variation in the threshold voltages of the transistors of the memory cells or degradation progressing over a long-time use. Moreover, the present invention achieves an advantage that, for example, in a normal operation mode of the semiconductor memory device, it is possible to supply to the memory cells a voltage which can ensure a proper operation margin, by changing the output of the voltage output circuit according to the characteristics of the memory cells monitored by the monitor circuit, without increasing a test cost, even when there is a manufacturing variation in the threshold voltages of the transistors of the memory cells or degradation progressing over a long-time use.

The above and further objects, features and advantages of the present invention will more fully be apparent from the following detailed description of preferred embodiments with accompanying drawings.

### BRIEF DESCRIPTION OF THE DRAWINGS

FIG. 1 is a block diagram showing a schematic configuration of a semiconductor integrated circuit system according to Embodiment 1 of the present invention.

FIG. 2 is a circuit diagram showing a memory cell constituting a memory cell array in a semiconductor memory device in the semiconductor integrated circuit system of FIG. 1.

FIG. 3 is a schematic circuit diagram showing a monitor circuit in the semiconductor integrated circuit system of FIG. 1.

FIG. 4 is a schematic circuit diagram showing a detecting circuit in the semiconductor integrated circuit system of FIG. 1.

FIG. 5 is a schematic circuit diagram showing a second voltage output circuit 4b in the semiconductor integrated circuit system of FIG. 1.

FIG. 6 is a schematic circuit diagram showing a detecting circuit in a semiconductor integrated circuit system according to Embodiment 2 of the present invention.

FIG. 7 is a schematic circuit diagram showing a power supply switching unit in a semiconductor integrated circuit system according to Embodiment 3 of the present invention.

FIG. 8 is a schematic circuit diagram showing a semiconductor integrated circuit system according to Embodiment 4 of the present invention.

FIG. 9 is a schematic circuit diagram showing a synchronous signal generating circuit in the semiconductor integrated circuit system of FIG. 8.

FIG. 10 is a timing chart of the semiconductor integrated circuit system of FIG. 8.

FIG. 11 is a schematic circuit diagram showing a monitor circuit in a semiconductor integrated circuit system according to Embodiment 6 of the present invention.

FIG. 12 is a schematic circuit diagram showing a semiconductor integrated circuit system according to Embodiment 6 of the present invention.

FIG. 13 is a block diagram showing a schematic configuration of electronic equipment according to Embodiment 7 of the present invention.

FIG. 14 is a block diagram showing a schematic configuration of electronic equipment according to Embodiment 8 of the present invention.

FIG. 15 is a graph showing a threshold voltage dependency of a memory cell of a semiconductor memory device.

### DETAILED DESCRIPTION OF THE PREFERRED EMBODIMENTS

### Conception of Invention

First of all, a conception of the present invention will be described.

In a semiconductor integrated circuit system including a semiconductor memory device, a transistor is incorporated into a memory cell constituting a memory cell array in the semiconductor memory device. In recent years, the semiconductor integrated circuit system has a problem that a leak current of a transistor increases with a progress of a manufacturing process for miniaturized constituents. In addition, with a higher functionality of a system, a capacity of a semiconductor memory device mounted thereinto tends to increase, and so, in the semiconductor integrated circuit system, electric power consumption in a memory cell array of the mounted semiconductor memory occupies a larger part of electric power consumption in the overall system. Therefore, there has been a need to reduce electric power consumption in the memory cell array of the semiconductor memory device.

The electric power consumption in the memory cell array can be reduced effectively, by setting a power supply voltage of the memory cells lower. In particular, the electric power consumption in the memory cell array in a stand-by mode in which a write operation and a read operation are not performed can be reduced effectively, by setting the power supply voltage of the memory cells lower and reducing a leak current.

However, if the power supply voltage of the memory cell is a predetermined voltage or less, then a data retaining ability of the memory cell is lost and stored data is erased. Therefore, it is necessary to set the power supply voltage in a range which is not less than a voltage with which all of the memory cells constituting the memory cell array of the semiconductor memory device can retain data.

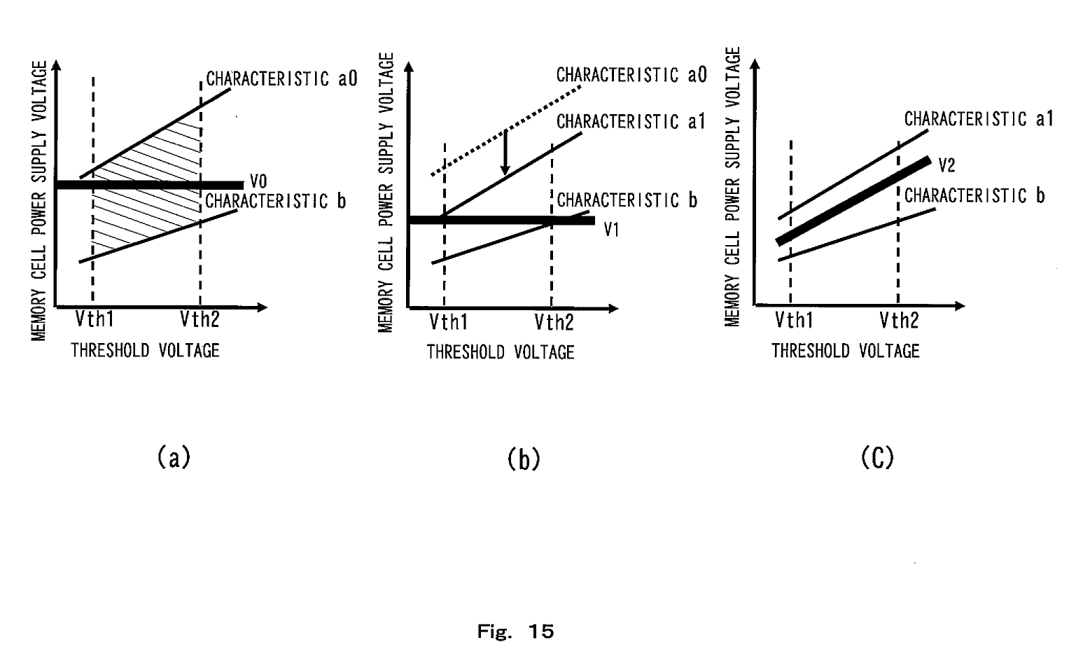

As mentioned above, with a progress of miniaturization of the memory cell array, a variation in characteristics of transistors manufactured, especially, a manufacturing variation in the threshold voltages is notable. If a manufacturing variation in the threshold voltages of the transistors increases, then it becomes difficult to achieve a leak current characteristic and a data retaining characteristic of the memory cells. This will be described with reference to FIG. 15. FIG. 15 is a graph showing a threshold voltage dependency of a memory cell voltage of a semiconductor memory device. In FIG. 15, characteristics a (a0, a1) indicate threshold voltage dependency of a leak characteristic of a memory cell for meeting a product standard regarding a leak current, and a characteristic b indicates a threshold voltage dependency of a data retaining characteristic of the memory cell. To be specific, to meet the product standard relating to the leak current of the semiconductor memory device, it is necessary to set an electric potential of the power supply voltage of the memory cell lower than that of the characteristic a. To retain data at a lower voltage, it is necessary to set the electric potential of the power supply voltage of the memory cell higher than that of the characteristic b. Threshold voltages Vth1 and Vth2 indicate corner conditions defining a manufacturing variation amount of the threshold voltages of the transistors. In other words, the threshold voltages of the transistors of the memory cells could have different values in a range from Vth1 to Vth2.

From the above, it is possible to easily achieve the leak current characteristic and the data retaining characteristic of the memory cell with the threshold voltage in a range from Vth1 to Vth2, if the power supply voltage of the memory cell can be set to a fixed voltage V0 which does not depend on the threshold voltage of the transistor of the memory cell, as shown in FIG. 15(a).

However, as shown in FIG. 15(b), when the leak current characteristic a shifts to a lower voltage from a0 to a1, because of an increase in the leak current of the transistor which would be caused by miniaturization of the memory cell array and a demand for lower electric power consumption of product, it is difficult to set the power supply voltage of the memory cell to a fixed voltage which does not depend on the threshold voltage of the transistor. Although the power supply voltage of the memory cell can be set to a fixed voltage V1 in the example shown in FIG. 15(b), a problem may arise due to a manufacturing variation in the threshold voltages of the transistors. To be specific, a transistor manufactured to have a threshold voltage near Vth1 can have a margin with respect to a lower limit value of a data retaining voltage for the data retaining characteristic b but cannot have a margin for the leak current characteristic a1. Therefore, there is a chance that the leak current characteristic cannot be satisfied if the threshold voltage of the transistor is lower than Vth1 due to the manufacturing variation or degradation progressing over time. In contrast, a transistor manufactured to have a threshold voltage near Vth2 can have a margin with respect to an upper limit value of a leak current voltage for the leak current characteristic a1 but cannot have a margin for the data retaining characteristic b, and therefore, there is a chance that the data retaining characteristic cannot be satisfied if the threshold voltage of the transistor is higher than Vth2 due to a manufacturing variation or degradation progressing over time.

As a solution to the above mentioned problems, sufficient margins can be provided effectively for the leak current characteristic and the data retaining characteristic irrespective of the threshold voltages of the transistors, for example, by a method in which the power supply voltage to be supplied is set higher as the threshold voltage of the transistor is higher and is set lower as the threshold voltage of the transistor is lower, like a voltage characteristic V2 shown in FIG. 15(c).

In view of the above explained principle, a semiconductor integrated circuit system and electronic equipment of the present invention are configured in such a manner that finish threshold voltages of transistors of memory cells are monitored within the semiconductor integrated circuit system and the electronic equipment, and a power supply voltage of a memory cell array is automatically set according to a result of the monitoring, thereby supplying a power supply voltage which allows the leak current characteristic and the data retaining characteristic to be satisfied well, without increasing a test cost, even when there is a characteristic variation due to a manufacturing variation or a characteristic fluctuation after a long-time use.

Hereinafter, preferred embodiments of the present invention will be described with reference to the drawings. Throughout the drawings, the same or corresponding constituents are designated by the same reference symbols and will not be described repetitively.

### Embodiment 1

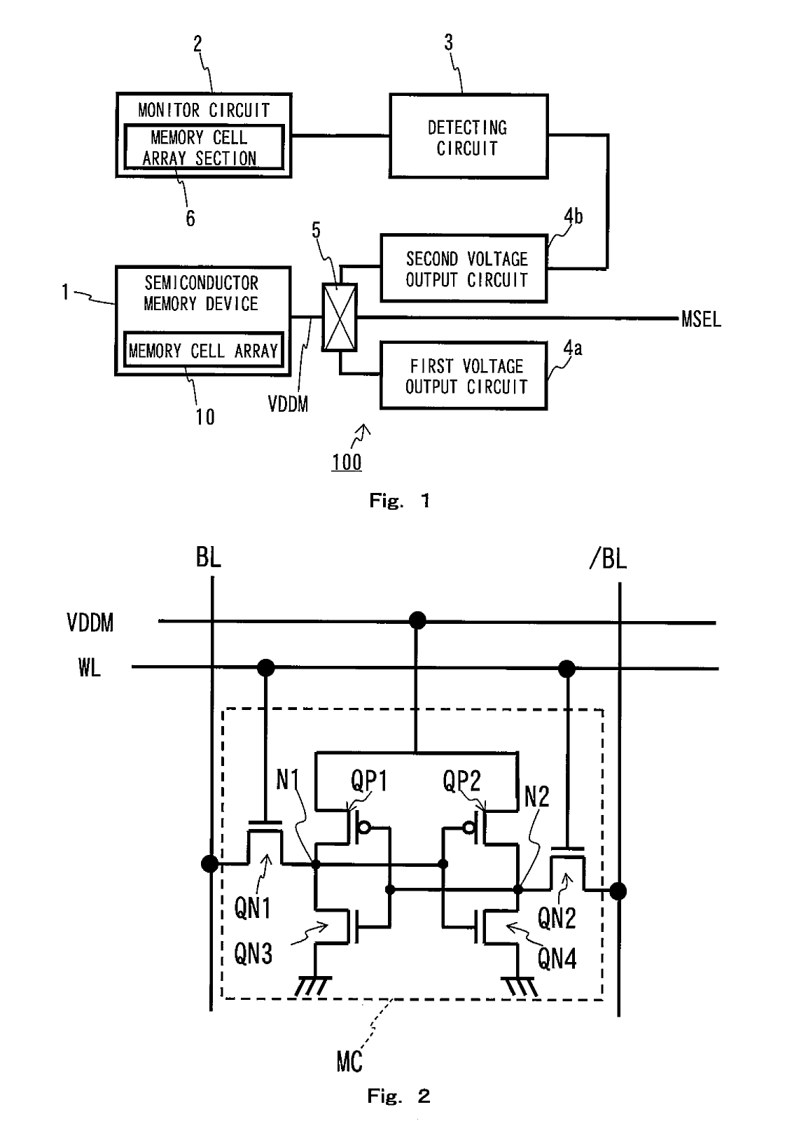

Initially, a semiconductor integrated circuit system according to Embodiment 1 of the present invention will be described. FIG. 1 is a block diagram showing a schematic configuration of a semiconductor integrated circuit system according to Embodiment 1 of the present invention.

In this embodiment, as shown in FIG. 1, a semiconductor integrated circuit system 100 includes a semiconductor memory device 1 including a memory cell array 10 having a plurality of memory cells. Further, the semiconductor integrated circuit system 100 includes voltage output circuits each of which outputs a power supply voltage to the memory cell array 10 in the semiconductor memory device 1. In this embodiment, as the voltage output circuits, first and second voltage output circuits 4a, 4b which output voltages different from each other are provided. The first voltage output circuit 4a or the second voltage output circuit 4b is selectively connected to the semiconductor memory device 1 via a switching circuit 5. The first voltage output circuit 4a or the second voltage output circuit 4b connected to the semiconductor memory device 1 supplies the power supply voltage to the memory cell array 10 in the semiconductor memory device 1.

The switching circuit 5 connects either one of the first and second voltage output circuits 4a, 4b to the memory cell array 10 in the semiconductor memory device 1 in accordance with a mode select signal MSEL supplied from outside. To be specific, in a state where the semiconductor memory device 1 is in a normal operation mode, the switching circuit 5 connects the first voltage output circuit 4a to the memory cell array 10 in the semiconductor memory device 1 (this mode is referred to as first mode), while in a state where the semiconductor memory device 1 is in a stand-by mode, the switching circuit 5 connects the second voltage output circuit 4b to the memory cell array 10 in the semiconductor memory device 1 (this mode is referred to as second mode).

In this embodiment, to reduce a leak current in the stand-by mode, an output voltage of the second voltage circuit 4b is set lower than an output voltage of the first voltage output circuit 4a. Although in this embodiment, the two voltage output circuits 4a, 4b for outputting voltages different from each other are provided, the present invention is not limited to this so long as a voltage output circuit is capable of changing a power supply voltage supplied to the semiconductor memory device 1. Alternatively, one voltage output circuit may be configured to change the power supply voltage supplied to the semiconductor memory device 1 as desired.

The semiconductor integrated circuit system 100 includes a monitor circuit 2 for monitoring a characteristic of the memory cell array 10 in the semiconductor memory device 1. The output of the monitor circuit 2 is detected by a detecting circuit 3 and digitalized. The digitalized output of the monitor circuit 2 is input to the second voltage output circuit 4b. The output voltage of the second voltage output circuit 4b is set according to the digitalized output of the monitor circuit 2 (i.e., output of the detecting circuit 3).

In accordance with the above configuration, the output of the monitor circuit 2 changes according to a finish threshold voltage of a transistor constituting a memory cell, and therefore the output voltage of the second voltage output circuit 4b changes according to a change in the output. By making a setting such that the power supply voltage of the memory cell array 10 in a state where the semiconductor memory device 1 is in a stand-by mode is set within the semiconductor integrated circuit system according to a manufacturing variation in the threshold voltages of the transistors of the memory cells, power supply voltage control according to the threshold voltage of the transistor of the memory cell can be carried out with high accuracy without increasing a test cost, even when there is a manufacturing variation in the threshold voltages of the transistors of the memory cells or degradation progressing over a long-time use. Therefore, it is possible to supply a power supply voltage which allows the leak current characteristic and the data retaining characteristic to be satisfied well, even when there is a manufacturing variation in the threshold voltages of the transistors of the memory cells or degradation progressing over a long-time use.

Note that the characteristic of the memory cell may be the threshold voltage of the transistor of the memory cell or a parameter which can be converted into the threshold voltage of the transistor of the memory cell, and the detected value may be a current value or a voltage value.

Hereinafter, constituents will be described in detail. FIG. 2 is a circuit diagram showing the memory cell constituting the memory cell array of the semiconductor memory device in the semiconductor integrated circuit system of FIG. 1. In this embodiment, the memory cell MC is configured as a holding circuit (CMOS-type SRAM memory cell) in which a CMOS circuit including two P-type MOS transistors QP1, QP2 and two N-type MOS transistors QN3, QN4 is caused to operate by two N-type MOS transistors QN1, QN2. Although the MOS transistors are used as the transistors constituting the memory cells MC, the present invention is not limited to these, so long as they are field effect transistors which have a problem associated with a leak current, and for example, junction field effect transistors may be used. Although the memory cell MC is configured by a complementary CMOS circuit, only P-type transistor or N-type transistor may be used to constitute a circuit.

The source terminals of the P-type MOS transistors QP1, QP2 are connected to a power supply line VDDM. The drain terminals of the P-type MOS transistors QP1, QP2 are connected to the drains terminals of N-type MOS transistors QN3, QN4, respectively. The source terminals of the N-type MOS transistors QN3, QN4 are electrically grounded. The drain terminals of the N-type MOS transistors QN1, QN2 are connected to a complementary bit line pair BL,/BL used to read data from the memory cell MC or write data to the memory cell MC. The source terminal of the N-type MOS transistor QN1 is connected to the drain terminals of the P-type MOS transistor QP1 and of the N-type MOS transistor QN3, while the source terminal of the N-type MOS transistor QN2 is connected to the drain terminals of the P-type MOS transistor QP2 and of the N-type MOS transistor QN4, The gate terminals of the N-type MOS transistors QN1, QN2 are connected to a word line WL used for selecting one of a plurality of memory cell MC columns.

A connection node of the drain terminals of the P-type MOS transistor QP1 and of the N-type MOS transistor QN3 and the source terminal of the N-type MOS transistor QN3 is a memory node N1 of the memory cell MC. A connection node of the drain terminals of the P-type MOS transistor QP2 and of the N-type MOS transistor QN4 and the source terminal of the N-type MOS transistor QN2 is a memory node N2 of the memory cell MC. The memory node N1 is connected to the gate terminals of the P-type MOS transistor QP2 and of the N-type MOS transistor QN4, while the memory node N2 is connected to the gate terminals of the P-type MOS transistor QP1 and of the N-type MOS transistor QN3.

In a normal operation mode, when the word line WL becomes High level, the N-type MOS transistors QN1, QN2 of the memory cell MC are turned ON, and data is read or written with respect to the memory nodes N1, N2 via the complementary bit line pair BL,/BL. In contrast, in a stand-by mode, the word line WL becomes Low level, and the N-type MOS transistors QN1, QN2 of the memory cell MC are turned OFF, so that the data at the memory nodes N1, N2 are retained therein.

The memory cell array 10 of the semiconductor memory device 1 is configured to include a plurality of memory cells MC having the above configuration. In this embodiment, a memory cell array section 6 in the monitor circuit 2 has at least one memory cell having the same configuration as the memory cell included in the memory cell array 10 of the semiconductor memory device 1. By detecting the characteristic (in this embodiment, leak current as described later) of the memory cell in the memory cell array section 6 in the monitor circuit 2, the characteristic of the memory cell in the memory cell array 10 of the semiconductor memory device 1 is indirectly detected.

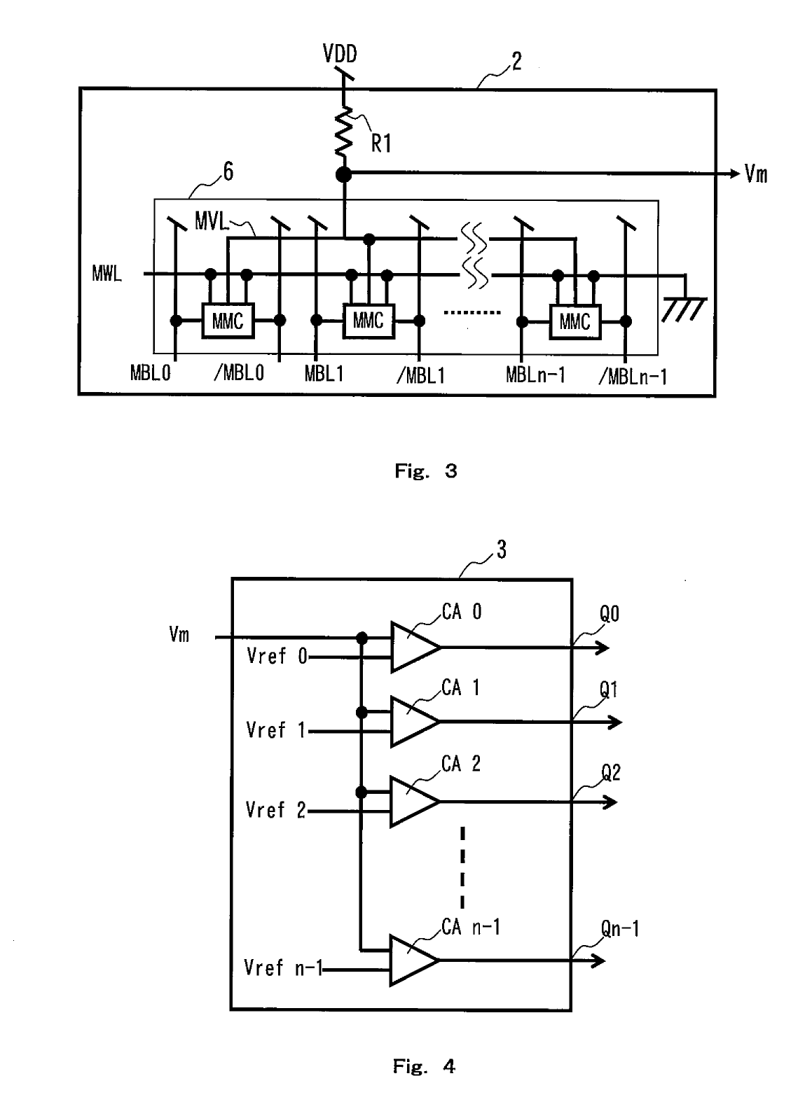

FIG. 3 is a schematic circuit diagram showing a monitor circuit in the semiconductor integrated circuit system of FIG. 1. Although the memory cells constituting the memory cell array section 6 in the monitor circuit 2 are depicted as MMC for the sake of convenience in FIG. 3, the memory cells MMC have the same configuration as that of the memory cell MC of the semiconductor memory device 1 of FIG. 2. The monitor circuit 2 is provided with a single monitor circuit word line MWL and a single monitor circuit power supply line MVL extending along a row direction of the memory cell array section 6, and n sets of monitor circuit complementary bit line pairs MBLn, /MBLn (n=0, 1, . . . , n−1) arranged along a column direction of the memory cell array section 6. n memory cells MMC are connected to the monitor circuit word line MWL and to the monitor circuit complementary bit line pairs MBLn, /MBLn. In other words, the source terminals of the P-type MOS transistors QP1, QP2 in the memory cell MC of FIG. 2 are connected to the monitor circuit power supply line MVL, while gate terminals of the N-type MOS transistors QN1, QN2 are respectively connected to the monitor circuit word line MWL. The drain terminals of the N-type MOS transistors QN1, QN2 are connected to the corresponding monitor circuit complementary bit line pairs MBLn, /MBLn. The present invention is intended to monitor the characteristics of the memory cells MC in the semiconductor memory device 1 statistically from the characteristics of the plurality of memory cells MMC and therefore, the number of the memory cells MMC in the memory cell array section 6 may be equal to or different from the number of the memory cells MC in the semiconductor memory device 1. Nonetheless, the memory cells MMC connected are preferably as many as possible to detect the characteristics of the memory cells MC with higher accuracy.

Since the monitor circuit 2 is provided to regulate the power supply voltage of the memory cell array 10 in a state where the semiconductor memory device 1 is in a stand-by mode in this embodiment, the memory cells MMC in the memory cell array section 6 are respectively biased to maintain a data retained state. That is, the word line MWL is fixed to Low level, while all of the complementary bit line pairs MBLn, /MBLn are fixed to High level.

The monitor circuit 2 includes a resistive element R1 which is a resistor section having one end connected to an outside power supply VDD and an opposite end connected to the power supply line MVL in the memory cell array section 6. That is, the monitor circuit power supply line MVL in the memory cell array section 6 is supplied with a power supply voltage from the outside power supply VDD via the resistive element R1. The monitor circuit 2 is provided to monitor the threshold voltages of the transistors in the memory cell array section 6 and is configured to output a voltage value Vm to the detecting circuit 3 through a node of an opposite end side of the resistive element R1. Thus, the monitor circuit 2 outputs as the output voltage Vm, a voltage generated by dropping the power supply voltage from the outside power supply VDD, by the resistive element R1. The output voltage Vm is expressed as Vm=VDD−Im×R1, using the outside power supply voltage VDD and the leak current Im. In other words, the output voltage Vm of the monitor circuit 2 can be converted into the leak current Im in the memory cell array section 6. Based on this leak current Im, the finish threshold voltage is monitored indirectly.

FIG. 4 is a schematic circuit diagram showing a detecting circuit in the semiconductor integrated circuit system of FIG. 1. The detecting circuit 3 detects the output voltage Vm associated with the leak current which is output from the monitor circuit 2, digitizes the output voltage Vm, and outputs the digitalized output voltage Vm to the second voltage output circuit 4b, and includes one or more comparators CAn (n=0, 1, . . . , n−1) for comparing the output voltage of the monitor circuit 2 to one or more reference voltages Vref (n) (n=0, 1, . . . , n−1). The number n of the comparators CAn connected is bit number n of digital value output.

The detecting circuit 3 is configured such that an input terminal of each of the comparators CAn is fed with the output Vm of the monitor circuit 2 and the reference voltage Vref (n). The reference voltage Vref(n) is a predetermined fixed voltage. A plurality of reference voltages Vref(n) are voltages different from each other. For example, Vref (0)>Vref (1)> . . . >Vref (n−1). The value and number of the reference voltages Vref (n) are set as desired according to assumed characteristics of the memory cells MC.

In the detecting circuit 3, each of the comparators CAn compares the output voltage Vm of the monitor circuit 2 to the reference voltage Vref (n) and outputs a result of comparison to an output terminal Qn of the comparator CAn. For example, when the output Vm of the monitor circuit 2 is higher than the reference voltage Vref (n), the output terminal Qn of the comparator CAn outputs High level. In other words, the output of the output terminal Qn is a n-bit output obtained by digitalizing the analog output Vm of the monitor circuit 2. For example, in a case where Vref (0)>Vref(1)> . . . >Vref (3)>Vm>Vref (4)>>Vref (n−1), the output voltage Vm is lower than the reference voltage Vref in each of the comparators CA0 to CA3, and therefore, each of the comparators CA0 to CA3 outputs Low level, while the output voltage Vm is higher than the reference voltage Vref in each of the comparators CA4 to CAn−1, and therefore, each of the comparators CA4 to CAn−1 outputs High level. Therefore, the outputs Qn of the detecting circuit 3 are (Q1, . . . , Q3, Q4, Qn−1)=(L, L, H, H). Since the voltage value Vm output from the monitor circuit 2 is digitized by the one or more comparators CAn, regulation of the second voltage output circuit 4b can be carried out easily in multi-levels.

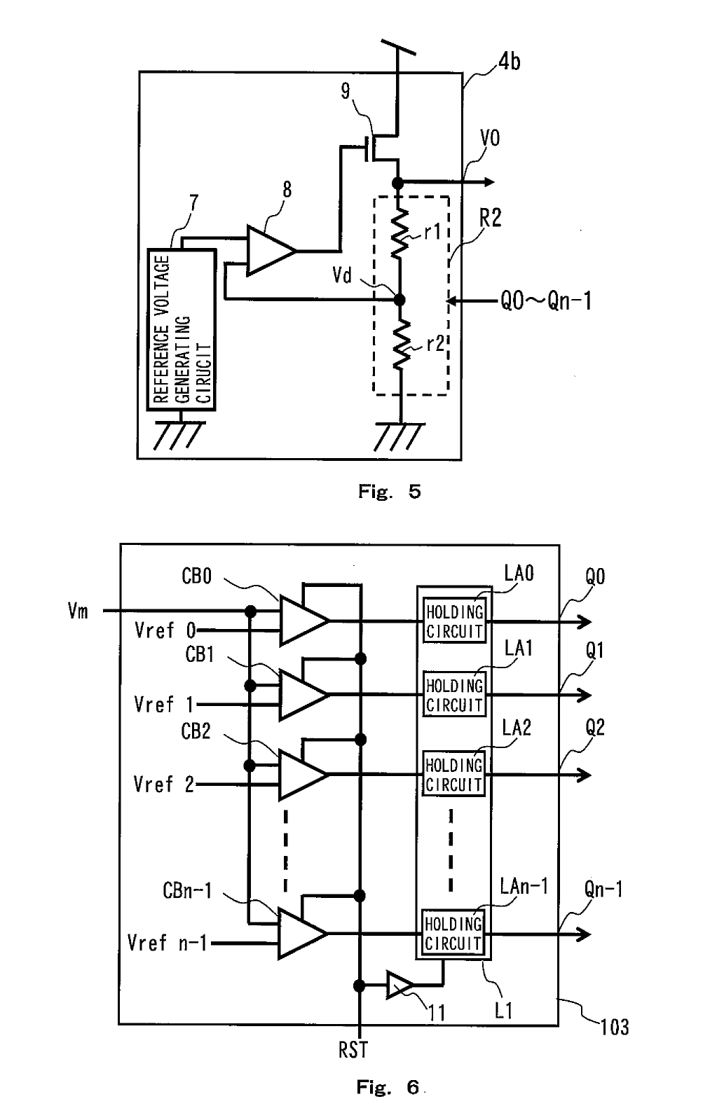

FIG. 5 is a schematic circuit diagram showing the second voltage output circuit 4b in the semiconductor integrated circuit system of FIG. 1. As described above, the second voltage output circuit 4b is configured to change the output voltage according to the output of the monitor circuit 2. To be specific, the second voltage output circuit 4b includes a variable resistor R2 for dividing an applied voltage according to the output of the monitor circuit 2 and is configured to change the output voltage according to a voltage dividing ratio of the variable resistor R2.

The variable resistor R2 receives as an input the output Qn of the detecting circuit 3 generated by digitalizing the output Vm of the monitor circuit 2 and divides the output Vm in a voltage dividing ratio of r2/r1 based on the output Qn.

The second voltage output circuit 4b further includes a reference voltage generating circuit 7 for generating a reference voltage, a differential amplifier 8 for comparing the reference voltage generated in the reference voltage generating circuit 7 to the voltage Vd generated by voltage division in the variable resistor R2 and amplifying the resulting difference, and an output transistor 9 which is operative based on the output of the differential amplifier 8. The output transistor 9 is interposed between a power supply and the variable resistor R2. The output transistor 9 of FIG. 5 is N-type MOS transistor, but is not limited to this. For example, the output transistor 9 may be a P-type MOS transistor or a junction transistor. Output terminal VO is connected to a node between the output transistor 9 and the variable resistor R2, and the voltage output from the output terminal VO is a power supply voltage supplied to the semiconductor memory device 1.

According to a change in the output voltage Vm of the monitor circuit 2, the voltage dividing ratio of r2/r1 with which the variable resistor R2 divides the output voltage Vm changes, and correspondingly the voltage Vd changes. According to the voltage Vd, the differential amplifier 8 controls the operation of the output transistor 9. For example, if a leak current increases in the memory cell array section 6 in the monitor circuit 2, the voltage Vm input to the detecting circuit 3 becomes lower, and as a result, the voltage dividing ratio r2/r1 increases. This increases the voltage Vd generated by voltage division and decreases the output voltage of the differential amplifier 8 (gate voltage of the output transistor 9). Since the voltage biased to the output transistor 9 becomes higher, the voltage at the output terminal VO becomes lower, and the power supply voltage supplied to the semiconductor memory device 1 becomes lower. Since the voltage at the output terminal VO is a voltage biased to the variable resistor R2, the output voltage at the output terminal VO is held within the second voltage output circuit 4b. In this way, by using the variable resistor R2, the power supply voltage supplied to the semiconductor memory device 1 can be changed with higher precision according to the output of the monitor circuit 2. The voltage dividing ratio r2/r1 of the variable resistor R2 is preset so that a voltage which is not less than a lower limit voltage with which the memory cell MC can retain data is output from the output terminal VO. As the voltage output circuit, a regulator capable of varying its output is used. In this embodiment, the output Qn of the detecting circuit 3 is converted into analog data by a D/A converter circuit which is not shown and input to the variable resistor R2, but the present invention is not limited to this. Furthermore, although in this embodiment, the variable resistor R2 (one variable resistor) having one input with respect to a n-bit output of the detecting circuit 3 is used, the present invention is not limited to this so long as the voltage Vd is generated by voltage division. For example, a plurality of resistor sections may be provided to receive as inputs one-bit outputs, respectively.

The first voltage output circuit 4a has a configuration substantially identical to that of the second voltage output circuit 4b, except that the second voltage output circuit 4a supplies a constant power supply voltage to the semiconductor memory device 1 and therefore does not have the variable resistor R2 (or, the voltage dividing ratio is fixed in the variable resistor R2). Since the power supply voltage output from the first voltage output circuit 4a is higher than the power supply voltage output from the second voltage output circuit 4b, it is desired that the output transistor 9 in the first voltage output circuit 4a be larger in size than the output transistor 9 included in the second voltage output circuit 4b.

The switching circuit 5 is configured as a power supply switching unit for selecting the voltage output circuit 4a or 4b to be connected to the semiconductor memory device 1 in accordance with a mode select signal MSEL which is changeable according to an operation mode of the semiconductor memory device 1. For example, when the semiconductor memory device 1 is placed in a normal operation mode, the mode select signal MSEL becomes High level, and the switching circuit 5 performs switching to connect the semiconductor memory device 1 to the first voltage output circuit 4a. On the other hand, when the semiconductor memory device 1 is placed in a stand-by mode, the mode select signal MSEL becomes Low level, and the switching circuit 5 performs switching to connect the semiconductor memory device 1 to the second voltage output circuit 4b.

As should be appreciated from the above, in accordance with the semiconductor integrated circuit system of this embodiment, it is possible to supply a power supply voltage which allows the leak current characteristic and the data retaining characteristic to be satisfied well to the memory cells MC constituting the memory cell array 10 in the semiconductor memory device 1, without increasing a test cost, even when there is a manufacturing variation in the threshold voltages of the transistors of the memory cells or degradation progressing over time.

### Embodiment 2

Subsequently, a semiconductor integrated circuit system according to Embodiment 2 of the present invention will be described. Embodiment 2 is different from Embodiment 1 in that a detecting circuit includes one or more holding circuits for holding output data of one or more comparators CAn. FIG. 6 is a schematic circuit diagram showing a detecting circuit in the semiconductor integrated circuit system according to Embodiment 2 of the present invention. Constituents other than the detecting circuit are identical to those of embodiment 1 and will not be described repetitively.

The detecting circuit 103 of this embodiment includes one or more comparators CBn (n=0, 1, . . . , n−1) for comparing the output voltage of the monitor circuit 2 to one or more reference voltages Vref (n) (n=0, 1, . . . , n−1). The detecting circuit 103 is configured such that an input terminal of each of the comparators CBn is fed with the output Vm of the monitor circuit 2 and the reference voltage Vref (n), like the detecting circuit 3 in the semiconductor integrated circuit system 100 of Embodiment 1. In addition, the detecting circuit 103 includes holding circuits LAn (n=0, 1, . . . , n−1) for holding the outputs of the comparators CBn, respectively. The holding circuits LAn are constituted by a logic circuit section L1 including a combination of logic circuits. The configuration of the holding circuits LAn is not particularly limited so long as the input data can be held until predetermined time.

The comparator CBn is configured to decide an output in response to a predetermined first signal. The holding circuit 103 is configured to, in response to a second signal, take in and hold output data from the comparator CBn at a time point when it receives the second signal sent after a lapse of a predetermined time after the first signal is sent. To be specific, the second signal is a signal generated from the first signal (in this embodiment, signal identical to the first signal). The second signal reaches the holding circuit LAn after a lapse of the predetermined time after the first signal reaches the comparator CBn. To be more specific, the first signal is a reset signal RST input to the semiconductor memory device when a power is ON. The detecting circuit 103 is configured such that an input terminal fed with the reset signal RST is connected to each of the comparators CBn, and is connected to the logic circuit section L1 via a delay buffer 11.

In accordance with the above configuration, the reset signal RST generated, for example, when the power is ON, is input to the detecting circuit 103. The reset signal RST input to the detecting circuit 103 is input to each of the comparators CBn as the first signal. Each of the comparators CBn compares the output voltage Vm of the monitor circuit 2 to the reference voltage Vref (n) at a timing when it receives the first signal, and decides the output. The reset signal RST is also input to the delay buffer 11 and then input to the logic circuit section L1 as the second signal, after a lapse of the predetermined time (reset time) determined by the delay time of the delay buffer 11. The holding circuits LAn take in and hold output data from the corresponding comparators CBn at timings when they receive the second signal. In other words, the holding circuits LAn digitalize and hold the output Vm of the monitor circuit 2 after a lapse of a reset time after the reset signal RST is received in the comparators CBn. Therefore, the detecting circuit 103 continues to output the output Qn of an equal value until it receives a reset signal RST next.

In a certain time period just after the power is ON, the output state of the monitor circuit 2 is sometimes unstable. If the output Vm of the monitor circuit 2 is obtained at such a timing and the second voltage output circuit 4b changes the power supply voltage supplied to the semiconductor memory device 1 based on the output Vm at such a timing, there may be a chance that the power supply voltage to be supplied is unstable and a voltage which does not allow the leak characteristic and the data retaining characteristic of the memory cell MC to be satisfied is supplied.

In contrast, in this embodiment, the power supply voltage supplied to the semiconductor memory device 1 is changed based on the voltage value at a time point when the second signal is sent after a lapse of the predetermined time after the first signal is sent, among the voltage values output from the monitor circuit 2. Therefore, the output of the monitor circuit 2 in a state where the output characteristic of the monitor circuit 2 is not stabilized yet just after the power is ON, etc, is not used as a reference for changing the power supply voltage supplied to the semiconductor memory device 1, which allows the power supply voltage to be supplied to the semiconductor memory device stably. Since the first signal and the second signal are the common reset signal RST input to the semiconductor memory device, signal wires can be effectively utilized and a circuit configuration is simplified.

### Embodiment 3

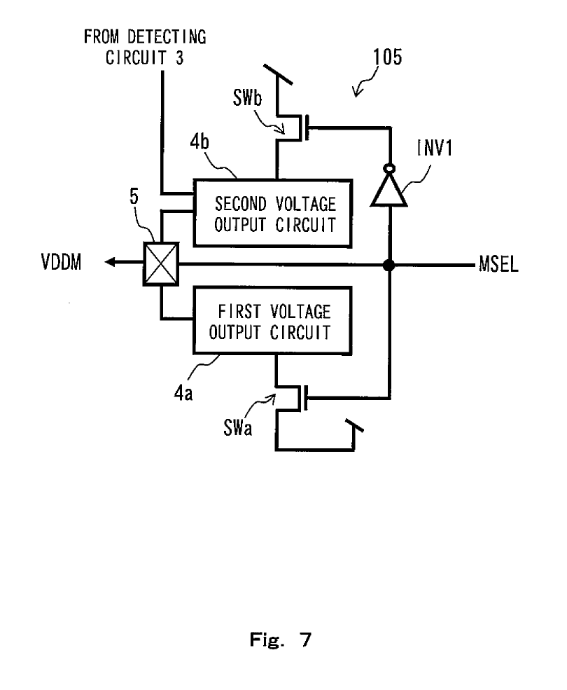

Subsequently, a semiconductor integrated circuit system according to Embodiment 3 of the present invention will be described. Embodiment 3 is different from Embodiment 1 in that the power supply switching unit is configured to permit the power supply voltage to be supplied to the first voltage output circuit 4a and inhibit the power supply voltage from being supplied to the second voltage output circuit 4b in a first mode in which the power supply switching unit connects the first voltage output circuit 4a to the semiconductor memory device 1, and permit power supply voltage to be supplied to the second voltage output circuit 4b and inhibit the power supply voltage from being supplied to the first voltage output circuit 4a in the second mode in which the power supply switching unit connects the second voltage output circuit 4b to the semiconductor memory device 1. FIG. 7 is a schematic circuit diagram showing a power supply switching unit in a semiconductor integrated circuit system according to Embodiment 3 of the present invention. Constituents other than the power supply switching unit are identical to those of embodiment 1 and will not be described repetitively.

In this embodiment, the power supply switching unit 105 includes the switching circuit 5 similar to that of Embodiment 1, a switch element SWa provided between an outside power supply for supplying the power supply voltage to the first voltage output circuit 4a and the first voltage output circuit 4a, and a switch element SWb provided between an outside power supply for supplying the power supply voltage to the second voltage output circuit 4b and the second voltage output circuit 4b. The switch element SWa or SWb is selectively turned ON in accordance with a mode select signal MSEL. Although in this embodiment, N-type MOS transistors are used as the switch elements SWa, SWb, for example, they may be P-type MOS transistors or junction field effect transistors, etc, so long as they can permit and inhibit the supply of the power supply voltage. The outside power supplies are connected to source terminals of the switch elements SWa, SWb, respectively, while the first and second voltage output circuits 4a, 4b are connected to the drain terminals of the switch elements SWa, SWb, respectively. The mode select signal MSEL is input to either one (in this embodiment, switch element SWa) of the gate terminals of the switch elements SWa, SWb, while an inverted input of the mode select signal MSEL is input to the other (in this embodiment switch element SWb). To generate the inverted input, an inverter INV1 is connected to the gate terminal of the other of the switch elements SWa, SWb.

In the above configuration, when the semiconductor memory device 1 is placed in the normal operation mode, the mode select signal MSEL becomes High level and the switching circuit 5 selects the first mode in which the semiconductor memory device 1 is connected to the first voltage output circuit 4a like Embodiment 1. In this case, the gate terminal of the switch element SWa for switching power supply to the first voltage output circuit 4a becomes High level, causing the switch element SWa to be turned ON, while the gate terminal of the switch element SWb for switching the power supply to the second voltage output circuit 4b becomes Low level by the inverter INV1, causing the switch element SWb to be turned OFF. As a result, the power supply voltage is supplied only to the first voltage output circuit 4a for supplying the power supply voltage to the semiconductor memory device 1, while the power supply voltage is inhibited from being supplied to the second voltage output circuit 4b.

On the other hand, when the semiconductor memory device 1 is placed in the stand-by mode, the mode select signal MSEL becomes Low level and the switching circuit 5 selects the second mode in which the semiconductor memory device 1 is connected to the second voltage output circuit 4b. In this case, the gate terminal of the switch element SWa becomes Low level, causing the switch element SWa to be turned OFF, while the gate terminal of the switch element SWb becomes High level by the inverter INV1, causing the switch element SWb to be turned ON. As a result, the power supply voltage is supplied only to the second voltage output circuit 4b for supplying the power supply voltage to the semiconductor memory device 1, while the power supply voltage is inhibited from being supplied to the first voltage output circuit 4a.

Thus, in accordance with this embodiment, the power supply voltage is inhibited from being supplied to one of the first and second voltage output circuits 4a, 4b, which is not connected to the semiconductor memory device 1. This lessens electric power consumption.

### Embodiment 4

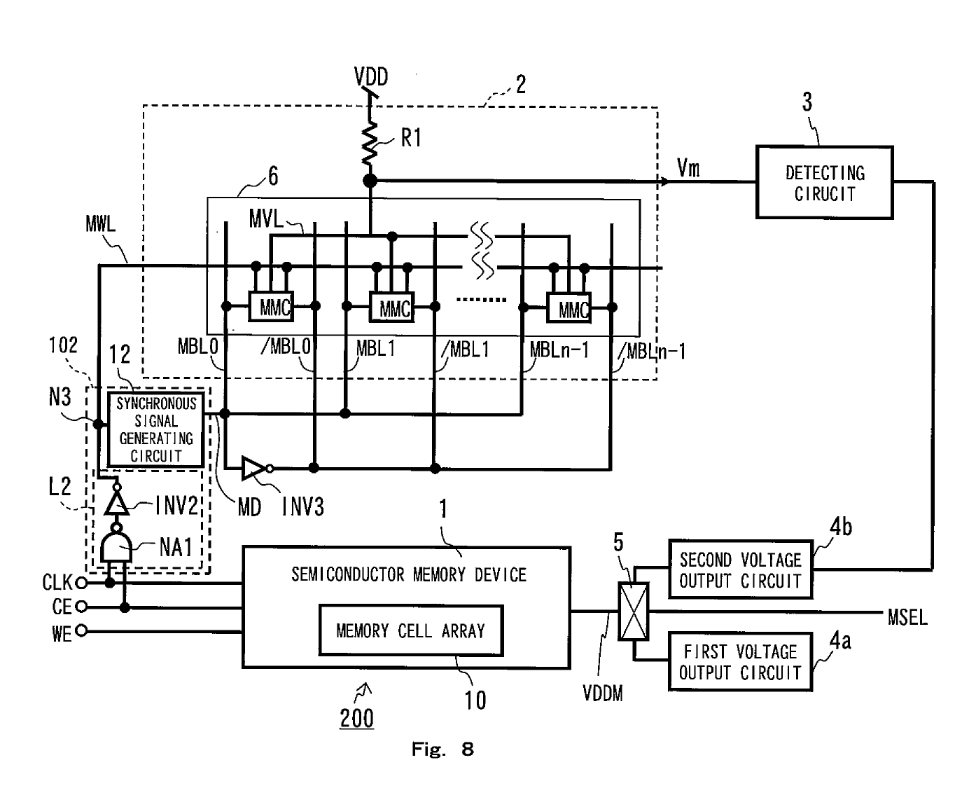

Subsequently, a semiconductor integrated circuit system according to Embodiment 4 of the present invention will be described. FIG. 8 is a schematic circuit diagram of a semiconductor integrated circuit system according to Embodiment 4 of the present invention. Embodiment 4 is different from Embodiment 1 in that a monitor circuit control unit 102 for switching the state of the memory cell MMC constituting the memory cell array section 6 in the monitor circuit 2 between Low level and High level is incorporated. In this embodiment, the monitor circuit control unit 102 is configured to switch the state of the memory cell MMC between Low level and High level, in accordance with a control signal of the semiconductor memory device 1.

The control signal of the semiconductor memory device 1 includes a clock signal CLK defining a clock frequency for controlling the semiconductor memory device, a chip enable signal CE for switching an operation mode of the semiconductor memory device 1, a write enable signal WE for switching between a write operation and a read operation which is to be performed by the semiconductor memory device. To be specific, the semiconductor memory device 1 is a synchronous semiconductor memory device which is operative synchronously with the clock signal CLK. The control signals CLK, CE, and WE are control signals transmitted from, for example, a main controller of electronic equipment (not shown) into which a semiconductor integrated circuit system 200 of this embodiment is incorporated. Here it is assumed that the semiconductor memory device 1 of this embodiment is configured to be placed in a normal operation mode when the chip enable signal CE is High level and in a stand-by mode when the chip enable signal CE is Low level. Also, it is assumed that the semiconductor memory device 1 is configured to perform a read operation when the write enable signal WE is Low level and a write operation when the write enable signal WE is High level.

The monitor circuit control unit 102 is configured to switch the state of the memory cell MMC in the memory cell array section 6 between Low level and High level, in accordance with the chip enable signal CE, in synchronization with the clock signal CLK.

To implement the above configuration, the monitor circuit control unit 102 in this embodiment detects the clock signal CLK and the chip enable signal CE and transmits a result of detection to the monitor circuit word line MWL and to the monitor circuit complementary bit line pairs MBLn, /MBLn (n=0, 1, . . . , n−1) in the memory cell array section 6. To be more specific, the monitor circuit control unit 102 includes a logic circuit section L2 in which the monitor circuit word line MWL is High level when the clock signal CLK and the chip enable signal CE are both High level, and a synchronous signal generating circuit 12 for generating a synchronous signal for synchronizing the monitor circuit complementary bit line pairs MBLn, /MBLn to the monitor circuit word line MWL in the memory cell array section 6.

The logic circuit section L2 includes a NAND circuit NA1 to which the clock signal CLK and the chip enable signal CE are input, and an inverter INV2 for inverting the output of the NAND circuit NA1 and outputting an inverted output. Although the logic circuit section L2 is configured as AND circuit constituted by the NAND circuit NA1 and the inverter INV2, the existing AND circuit may be used for the logic circuit section L2.

The synchronous signal generating circuit 12 is connected at an input side to a branch node N3 which is at an output side of the logic circuit section L2 and connected at an output side to each of the monitor circuit bit lines MBLn. The output side of the synchronous signal generating circuit 12 is also connected to each of the monitor circuit inverting bit lines /MBLn via the inverter INV3. Thereby, every time the semiconductor memory device is accessed and the monitor circuit word line MWL becomes High level, the output of the synchronous signal generating circuit 12, i.e., the monitor circuit complementary bit line pairs MBLn, /MBLn in the memory cell array section 6 are inverted, so that storing states of the memory cells MMC can be inverted. In this way, the memory cells MMC in the memory cell array section 6 performs a write operation like the memory cells MMC in the semiconductor memory device 1 in accordance with the output of the synchronous signal generating circuit 12.

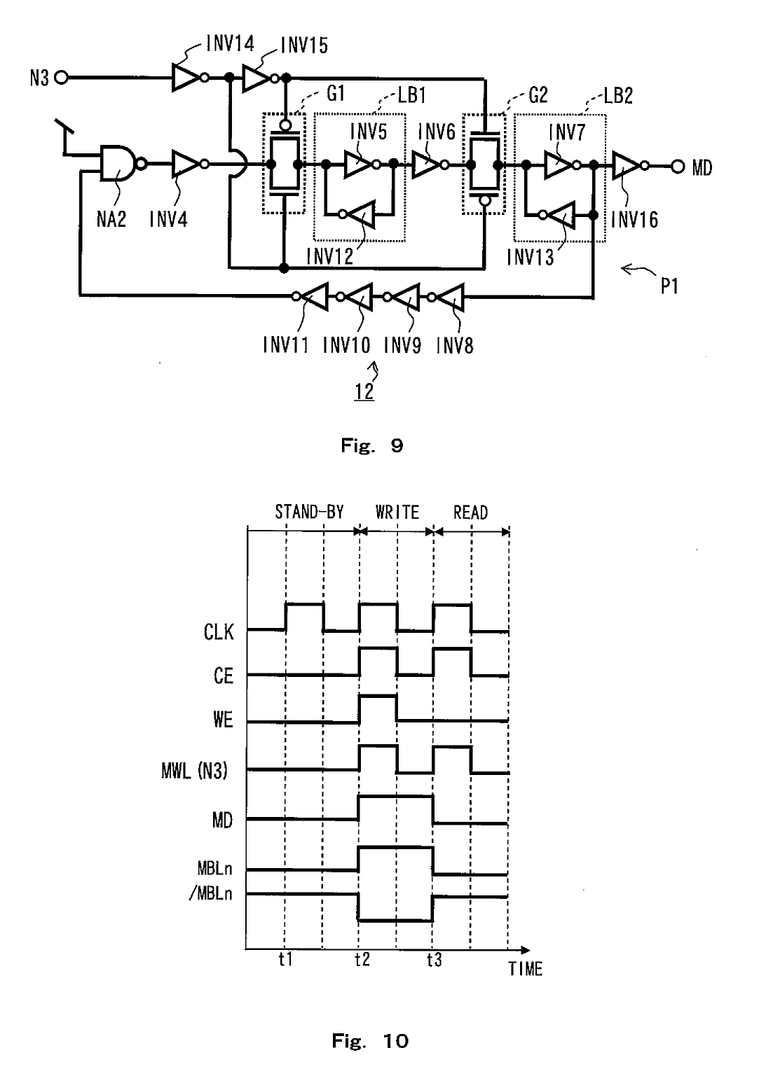

Subsequently, the synchronous signal generating circuit 12 will be described in detail. FIG. 9 is a schematic circuit diagram showing the synchronous signal generating circuit in the semiconductor integrated circuit system of FIG. 8. The synchronous signal generating circuit 12 includes a loop circuit section P1 consisting of a plurality of inverters, first and second holding circuit sections LB1, LB2 provided in the loop circuit section, and first and second switch elements G1, G2 provided in the loop circuit section to control data inputting to respective of first and second holding circuits according to the state of the monitor circuit word line MWL, respectively.

The loop circuit section P1 includes a NAND circuit NA2 to which a power supply voltage is input and a feedback output from the second holding circuit is input via a feedback passage, and inverters INV4˜INV11 of even number which are connected in series in a loop circuit form from the output of the NAND circuit NA2 to the input of the NAND circuit NA2. One of inputs of the NAND circuit NA2 is the power supply voltage and therefore is always High level. Therefore, the NAND circuit NA2 is operative as an inverter for inverting the feedback output. In other words, the loop circuit section P1 is operative as a ring oscillator including inverters of an odd number.

The first holding circuit section LB1 includes an inverter INV5 which is a constituent of the ring oscillator and an inverter INV12 which is a constituent of the ring oscillator and is connected in parallel with the inverter INV5, while the second holding circuit section LB2 includes an inverter INV7 which is a constituent of the ring oscillator and an inverter INV13 which is a constituent of the ring oscillator and is connected in parallel with the inverter INV7. The outputs of the inverters INV5 and INV7 are input to the inverters INV12 and INV13, respectively. The outputs of the inverters INV12 and INV13 are input to the inverters INV5 and INV7, respectively. Thus, each of the first and second holding circuit sections LB1, LB2 inverts an input signal and outputs the inverted signal and holds its state.

The first and second switch elements G1, G2 are constituted by transfer gates, respectively. The first and second holding circuit sections LB1, LB2 are connected to the outputs of the transfer gates, respectively. Complementary input from a branch node N3 is input to the gate terminals of the first and second switch elements G1, G2, via the two inverters INV14, INV15. To be specific, when the first switch element G1 is in ON-state, the second switch element G2 is in OFF-state, while the first switch element G1 is in OFF-state, the second switch element G2 is in ON-state.

An inverter INV6 which is a constituent of the ring oscillator is interposed between the first holding circuit section LB1 and the second switch element G2. The output side of the second holding circuit section LB2 branches into a feedback passage including four inverters INV8˜INV11 connected in series and an output passage to which an inverter INV16 for inverting the output of the second holding circuit section LB2 and outputting the inverted output is connected. The output of the inverter INV11 in the feedback passage is input to the NAND circuit NA2 as a feedback output. An output signal MD output through the output passage is write data to the memory cell MMC in the memory cell array section 6.

An operation of the synchronous signal generating circuit 12 having the above configuration will be described. Initially, when a signal level of the monitor circuit word line MWL is Low level, Low level is input to the synchronous signal generating circuit 12 through the branch node N3. Thereby, the first switch element G1 is turned ON and the second switch element G2 is turned OFF. Assuming that the signal level of a previous output signal MD was Low, High level is input to the NAND circuit NA2 and the NAND circuit NA2 outputs Low level. Therefore, High level is input to the first holding circuit section LB1 via the inverter INV4. The first holding circuit section LB1 holds an inverted input signal and hence Low level. In this way, the signal level of the previous output signal MD is held in the first holding circuit section LB1.

Thereafter, when the signal level of the monitor circuit word line MWL becomes High level, the first switch element G1 is turned OFF and the second switch element G2 is turned ON. Thereby, data held in the first holding circuit section LB1 is inverted by the inverter INV6 and input to the second holding circuit LB2. Like the above described example, in a case where the first holding circuit LB1 holds Low level, High level is input to the second holding circuit LB2 and the second holding circuit LB2 holds Low level which is inverted state of High level. In this case, the output signal MD is High level resulting from inversion by the inverter INV16.

After that, when the signal level of the monitor circuit word line MWL becomes Low level, the first switch element G1 is turned ON and the second switch element G2 is turned OFF. Thereby, the signal level of the output signal MD is held in the first holding circuit section LB1. At this time, the second holding circuit LB2 holds a state before the signal level of the word line MWL becomes Low level. To be specific, like the above example, in a case where the signal level of the output signal MD was High level in a state before the signal level of the monitor circuit word line MWL becomes Low level, the first holding circuit section LB1 holds High level and the second holding circuit section LB2 holds Low level. Therefore, the output signal MD is held at High level.

When the signal level of the word line MWL becomes High level again, data held in the first holding circuit section LB1 is inverted by the inverter INV6 and input to the second holding circuit LB2. Therefore, the signal level of the output signal MD is held in an inverted state.

As should be appreciated from the above, in accordance with the synchronous signal generating circuit 12 having the above configuration, the signal level of the output signal MD is inverted only when the signal level of the monitor circuit word line MWL transitions from Low level to High level, while the signal level of output signal MD is not inverted when the signal level of the monitor circuit word line MWL transitions from High level to Low level, and is held until the signal level of the monitor circuit word line MWL transitions to High level next.

Hereinafter, an operation of the semiconductor integrated circuit system 200 including the synchronous signal generating circuit 12 having the above configuration will be described. FIG. 10 is a timing chart of the semiconductor integrated circuit system of FIG. 8.

As shown in initial state of the timing chart of FIG. 10, for example, the clock signal CLK, the chip enable signal CE, and the write enable signal WE are Low level. At this time, the monitor circuit word line signal MWL in the memory cell array section 6 is Low level. The output signal MD of the synchronous signal generating circuit 12 could have an arbitrary level but is assumed to be Low level, for example. In this case, the monitor circuit bit line signal MBLn in the memory cell array section 6 is Low level, while the monitor circuit inverting bit line /MBLn in the memory cell array section 6 is High level. The clock signal CLK is High level for a specified period from time t1, for a specified period from time t2, and for a specified period from time t3.

At time t1, the chip enable signal is Low level, and therefore, the semiconductor memory device 1 is in a stand-by mode in which the memory cell MC does not perform a read operation or a write operation. In this case, a signal level at the branch node N3 which is the output of the logic circuit section L2 is Low level, and therefore, the signal level of the monitor circuit word line MWL is Low level. At this time, the state of the memory cell array section 6 is substantially identical to the state of the memory cell array section 6 of Embodiment 1, in which the signal level of the monitor circuit word line MWL is fixed at Low level. In the stand-by mode, the signal level of the output signal MD of the synchronous signal generating circuit 12 is Low level which is an initial state.

Then, at time t2, when the clock signal CLK and the chip enable signal CE become High level, the semiconductor memory device 1 enters a normal operation mode. At time t2, the write enable signal WE also becomes High level, and therefore the semiconductor memory device 1 enters a write operation mode. At this time, the signal level at the branch node N3 which is the output of the logic circuit section L2 becomes High level, and therefore, the monitor circuit word line MWL becomes High level. As a result, the signal level of the output signal MD in the synchronous signal generating circuit 12 is inverted and transitions from Low level in an initial state to High level. Thereby, the complementary bit line pairs MBLn, /MBLn in the memory cell array section 6 are respectively inverted and data retained in the memory cells MMC constituting the monitor circuit 2 are rewritten. Thereafter, when the clock signal CLK, the chip enable signal CE and the write enable signal WE transition to Low level, the signal level of the word line MWL transitions to Low level, but the signal level of the output signal MD in the synchronous signal generating circuit 12 is maintained at High level.

Following this, at time t3, the clock signal CLK and the chip enable signal CE become High level and the write enable signal WE is maintained at Low level. Thereby, the semiconductor memory device 1 enters a read operation mode. At this time, the signal level at the branch node N3 which is the output of the logic circuit section L2 becomes High level and therefore, the signal level of the word line MWL becomes High level. As a result, the signal level of the output signal MD of the synchronous signal generating circuit 12 is inverted and transitions from High level to Low level. Thereby, the monitor circuit complementary bit line pairs MBLn, /MBLn in the memory cell array section 6 are respectively inverted and data retained in the memory cells MMC constituting the monitor circuit 2 are rewritten. Thereafter, when the clock signal CLK, the chip enable signal CE and the write enable signal WE transition to Low level, the signal level of the word line MWL transitions to Low level but the signal level of the output signal MD in the synchronous signal generating circuit 12 is maintained at Low level.

In the stand-by mode, the memory cell array 10 of the semiconductor memory device is in a data retained state where the voltage levels of the word lines and the voltage levels of the complementary bit line pairs are constant, while in the operation mode, the voltage levels of the word lines and the voltage levels of the complementary bit line pairs change repetitively every time the memory cells are accessed. There is a chance that characteristics of the memory cells, after such a change in the voltage levels occurred during a long-time use, may be different from characteristics of the memory cells which maintain certain voltage levels.

Accordingly, in accordance with the semiconductor integrated circuit system of this embodiment, as described above, every time the semiconductor memory device is accessed and the monitor circuit word line MWL becomes High level, the states of the memory cells MMC in the memory cell array section 6 in the monitor circuit 2 are rewritten to Low level or to High level. For this reason, a characteristic change in the memory cells MMC in the monitor circuit 2 after a long-time use can be made closer to a characteristic change in the memory cells MC in the semiconductor memory device 1, and the monitor circuit 2 can monitor the characteristics of the memory cells MC with high accuracy in a long-time use.

### Embodiment 5

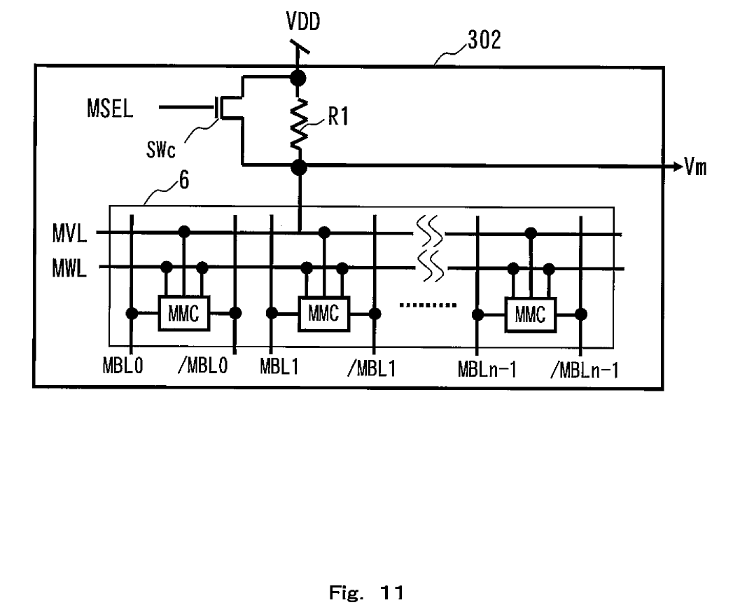

Subsequently, a semiconductor integrated circuit system according to Embodiment 5 of the present invention will be described. Embodiment 5 is different from Embodiment 1 in that a monitor circuit includes a switch element connected in parallel with a resistor section and the switch element is turned ON when the semiconductor memory device is connected to the first voltage output circuit and is turned OFF when the semiconductor memory device is connected to the second voltage output circuit. FIG. 11 is a schematic circuit diagram showing a monitor circuit in a semiconductor integrated circuit system according to Embodiment 6 of the present invention. Constituents other than the monitor circuit are identical to those of Embodiment 1 and will not be described repetitively.

In this embodiment, the monitor circuit 302 includes a resistive element R1 which is a resistor section having one end connected to an outside power supply VDD and an opposite end connected to the power supply line MVL in the memory cell array section 6, and a switch element SWc connected in parallel with the resistive element R1. The switch element SWc in FIG. 11 is constituted by a N-type MOS transistor. The source terminal and the drain terminal of the switch element SWc are connected to both ends of the resistive element R1. A mode select signal MSEL is input to the gate terminal of the switch element SWc. Although in this embodiment, the switch element SWc is constituted by a N-type MOS transistor, the present invention is not limited to this so long as it can switch between ON and OFF in accordance with the mode select signal. For example, the switch element SWc may be other transistor element such as a P-type MOS transistor, or other switch element.

As described above in Embodiment 1, when the semiconductor memory device 1 is in a stand-by mode, the mode select signal MSEL is Low level, while when the semiconductor memory device 1 is in a normal operation mode, the mode select signal MSEL is High level. Therefore, the switch element SWc is OFF in a state where the semiconductor memory device 1 is in the stand-by mode, while the switch element SWc is ON in a state where the semiconductor memory device 1 is in the normal operation mode.

In a state where the semiconductor memory device 1 is in the stand-by mode, the switch element SWc is OFF and a voltage generated by dropping the power supply voltage from the power supply VDD by the resistive element R1 is supplied to the power supply of the memory cell array section 6. To be specific, a state similar to Embodiment 1 is created, and the monitor circuit 2 outputs as output Vm, a voltage equivalent value of a leak current. On the other hand, in a state where the semiconductor memory device 1 is in the normal operation mode, and the switch element SWc is OFF, the both ends of the resistive element R1 are short-circuited, so that the power supply voltage is directly supplied from the outside power supply VDD to the power supply in the memory cell array section 6.

If the resistive element R1 for detecting a leak current is interposed between the outside power supply VDD and the memory cell array section 6, a voltage lower than the power supply voltage supplied to the memory cell array 10 in the semiconductor memory device 1 is always supplied to the power supply in the memory cell array section 6 in the memory circuit 2. A characteristic of the memory cell supplied with the power supply voltage lower than the voltage of the outside power supply becomes different from the characteristic of the memory cell MC in the memory array 10 which is directly supplied with the power supply voltage from the outside power supply VDD, after a long-time use, and as a result, its characteristic could not be monitored accurately.

As a solution to this, in accordance with the semiconductor integrated circuit system of this embodiment, in the normal operation mode in which the first voltage output circuit 4a outputting a steady voltage is connected to the power supply line of the memory array of the semiconductor memory device, the outside power supply VDD and the memory cell array section 6 are short-circuited. Therefore, a voltage supplied to the memory cell MMC in the memory cell array section 6 can be made equal to the voltage supplied to the memory cell MC in the semiconductor memory device 1. As a result, the power supply voltage of the memory cell MC in the semiconductor memory device 1 can be controlled with accuracy even when there is a characteristic variation after a long-time use.

### Embodiment 6

Subsequently, a semiconductor integrated circuit system according to Embodiment 6 of the present invention will be described.

A semiconductor memory device has a problem that a characteristic variation in transistors constituting memory cells increases, a circuit operation margin decreases, and design is difficult, due to an increase in a variation in process associated with a progress of a process for manufacturing miniaturized constituents, and this problem is notable. To implement a stable operation with an increased circuit operation margin, assist circuits such as a write assist circuit for improving a write characteristic and a read assist circuit for improving a read characteristic are mounted, according to finish thresholds of transistors constituting memory cells. Although a detailed principle is not described in detail, these assist circuits are configured to supply an auxiliary voltage different from an operating voltage of the semiconductor integrated circuit system to a memory cell array power supply, thereby increasing an operation margin of the semiconductor memory device. It is essential that the assist circuits be mounted in the system to ensure the operation margin of the semiconductor memory device, for the purpose of addressing an increase in a variation in the threshold voltages of the transistors. A method is known, in which to address an increase in a variation in the manufacturing process which arises from a progress of the process for miniaturized constituents, a tester outside the semiconductor integrated circuit system monitors finish threshold voltages of the transistors constituting the memory cells and programs setting of assist conditions according to a result of the monitoring.

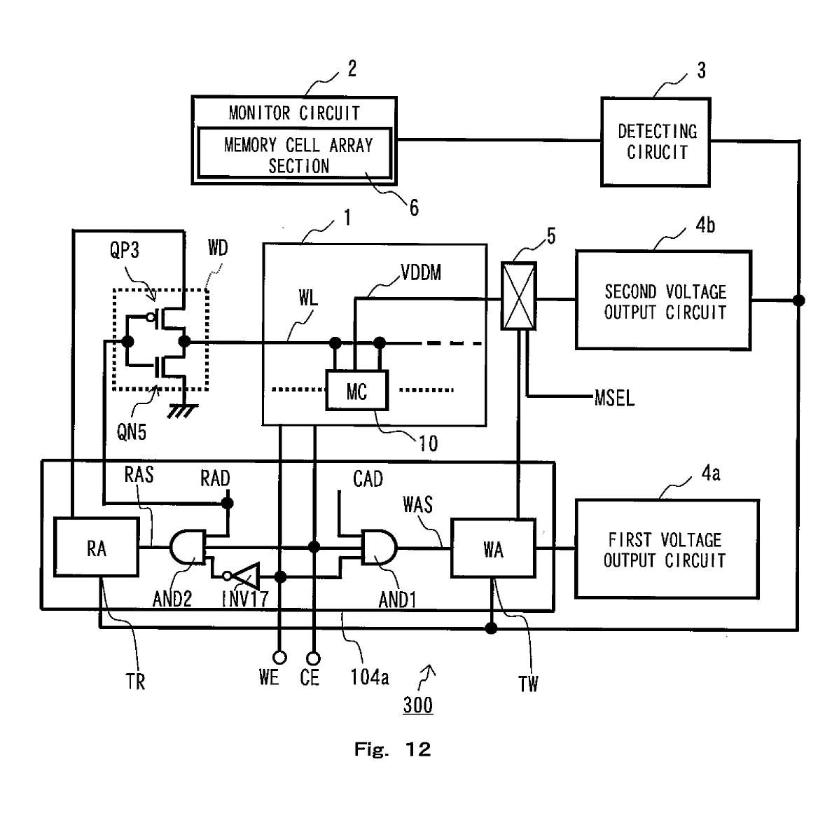

This embodiment is different from Embodiment 1 in that the power supply voltage of the memory cell array 10 of the semiconductor memory device is changed according to the output of the monitor circuit in the write operation of the semiconductor memory device, and the word line voltage of the memory cell array 10 in the semiconductor memory device is changed according to the output of the monitor circuit in the read operation of the semiconductor memory device. FIG. 12 is a schematic circuit diagram showing a semiconductor integrated circuit system according to Embodiment 6 of the present invention.

Like the voltage output circuit of Embodiment 1, the voltage output circuit of this Embodiment includes the first and second voltage output circuits 4a, 4b one of which is selectively connected to the semiconductor memory device 1 via the switching circuit 5. Like the second voltage output circuit 4b of Embodiment 1, the second voltage output circuit 4b is configured to change the output voltage according to the output of the monitor circuit. In contrast, the first output circuit 4a of this embodiment outputs a normal voltage which is supplied to the power supply of the memory cell array 10 of the semiconductor memory device 1 via a write assist circuit described below. The output of the second voltage output circuit 4b or the output of the first voltage output circuit 4a via the write assist circuit is selected by the switching circuit 5 and supplied to the memory cell array 10.

A semiconductor integrated circuit system 300 of this embodiment includes an assist circuit section 104a consisting of a write assist circuit WA for regulating a power supply voltage supplied from the first voltage output circuit 4a according to the output of the detecting circuit 3 in a write operation mode of the memory cell array 10 in the semiconductor memory device 1, and a read assist circuit RA for regulating a word line voltage of the semiconductor memory device 1 according to the output of the detecting circuit 3 in a read operation mode of the memory cell array 10 in the semiconductor memory device 1.

The write assist circuit WA in the assist circuit section 104a has an input terminal connected to an output terminal of the first voltage output circuit 4a and an output terminal connected to an input terminal of the switching circuit 5 and is connected to the power supply line VDDM of the memory cell array 10 via the switching circuit 5. The write assist circuit WA includes an output voltage regulating terminal TW to which the output of the detecting circuit 3 is input. The write assist circuit WA is configured to receive a write assist circuit activation signal WAS which is generated based on an input signal to the semiconductor memory device 1 and is used for outputting a regulated voltage from the write assist circuit WA. To be specific, the output of a 3-input AND circuit AND1 which is fed with the chip enable signal CE of the semiconductor memory device 1, the write enable signal WE, and a column address signal CAD based on column address specifying information which is sent from a main controller or the like in electronic equipment which is not shown, is input to the write assist circuit WA as the write assist circuit activation signal WAS.

The write assist circuit WA outputs the power supply voltage supplied from the first voltage output circuit 4a when the write assist circuit activation signal WAS is Low level, while the write assist circuit WA outputs an auxiliary voltage lower than the power supply voltage supplied from the first voltage output circuit 4a when the write assist circuit activation signal WAS is High level. The auxiliary voltage is controlled according to the output of the detecting circuit 3.

The read assist circuit RA of the assist circuit section 104a has an output terminal connected to a power supply terminal of a word line driver WD for driving the word line WL of the semiconductor memory device 1. The read assist circuit RA includes an output voltage regulating terminal TR to which an output of the detecting circuit 3 is input. The read assist circuit RA is configured to receive a read assist circuit activation signal RAS which is generated based on an input signal to the semiconductor memory device 1 and is used for outputting a regulated voltage from the read assist circuit RA. To be specific, the output of a 3-input AND circuit AND2 which is fed with the chip enable signal CE of the semiconductor memory device 1, an inverted output of the write enable signal WE, and a row address signal RAD based on row address specifying information which is sent from a main controller or the like in electronic equipment, which is not shown, is input to the read assist circuit RA. The inverter INV17 for generating an inverted output of the write enable signal WE is connected to one of inputs of the AND circuit AND2.

The word line driver WD includes a P-type MOS transistor QP3 and a N-type MOS transistor QN5 which are arranged complementarily, thereby forming a CMOS circuit. The drain terminal of the P-type MOS transistor QP3 and the drain terminal of the N-type MOS transistor QN5 are connected to each other. The output terminal of the read assist circuit RA is connected to the source terminal of the P-type MOS transistor QP3, while the source terminal of the N-type MOS transistor QN5 is electrically grounded. The row address signal RAD is input to the gate terminal of the P-type MOS transistor QP3 and to the gate terminal of the N-type MOS transistor QN5.

The read assist circuit RA outputs a power supply voltage of a power supply (not shown) provided within or outside the read assist circuit RA when the read assist circuit activation signal RAS is Low level, while the read assist circuit RA outputs an auxiliary voltage lower than the power supply voltage of the read assist circuit RA when the read assist circuit activation signal RAS is High level. The auxiliary voltage is controlled according to the output of the detecting circuit 3. The power supply voltage of the read assist circuit RA may be the power supply voltage supplied from the first voltage output circuit 4a or another power supply voltage.

The operation of the semiconductor integrated circuit system 300 of this embodiment in a state where the semiconductor memory device 1 is in the normal operation mode will be described in detail. When the semiconductor memory device 1 is in the normal operation mode, the first voltage output circuit 4a is connected to the power supply VDDM of the memory cell array 10 of the semiconductor memory device 1 via the write assist circuit WA to supply the power supply voltage.

In the write operation, as described in Embodiment 4, the chip enable signal CE and the write enable signal WE are High level. When the memory cell MC of a column address signal to which data is to be written, is selected, the corresponding column address signal CAD is High level, and the write assist circuit activation signal WAS which is the output of the 3-input AND circuit AND1 is High level (write-enable state). Under this condition, the write assist circuit WA outputs the auxiliary voltage lower than the output voltage of the first voltage output circuit 4a to supply the power supply voltage to the memory cell MC. At this time, the output of the detecting circuit 3 is input to the output voltage regulating terminal TW of the write assist circuit WA, and the write assist circuit WA outputs the voltage regulated according to the output of the detecting circuit 3 as the auxiliary voltage. This makes it easy to carry out writing in the semiconductor memory device according to a manufacturing variation. A voltage drop amount or a regulating range of the auxiliary voltage may be pre-set to attain an auxiliary voltage which surely allows a write operation, to address reduction of a write operation margin of the memory cell MC which occurs due to an assumed variation in the threshold voltages of the memory cells MC.

In the write operation, since an inverted signal of the write enable signal WE is Low level, and therefore, the read assist circuit activation signal RAS which is the output of the 3-input AND circuit AND 2 is Low level. Thereby, the read assist circuit RA outputs the power supply voltage of the power supply provided within or outside the read assist circuit RA, to the power supply terminal of the word line driver WD. Therefore, the word line WL of the semiconductor memory device 1 is driven by the power supply voltage from the read assist circuit RA.

In the read operation, the chip enable signal CE and the inverted signal of the write enable signal WE are High level. Further, when the memory cell MC of the row address from which data is to be read is selected, the corresponding row address signal RAD is High level, and the read assist circuit activation signal RAS which is the output of the 3-input AND circuit AND 2 is high level (read-enable state). Under this condition, the read assist circuit RA outputs the auxiliary voltage lower than the power supply voltage to supply it to the power supply terminal of the word line driver WD. At this time, the output of the detecting circuit 3 is input to the output voltage regulating terminal TR of the read assist circuit RA, and the read assist circuit RA outputs the voltage regulated according to the output of the detecting circuit 3 as the auxiliary voltage. This makes it easy to carry out reading in the semiconductor memory device according to a manufacturing variation. A voltage drop amount or a regulating range of the auxiliary voltage may be pre-set to attain an auxiliary voltage which surely allows a write operation to address reduction of a read operation margin of the memory cell MC which occurs due to an assumed variation in the threshold voltages of the memory cells MC.

In the read operation, the write enable signal WE is Low level and therefore, the write assist circuit activation signal WAS which is the output of the 3-input AND circuit AND 1 is Low level. Thereby, the write assist circuit WA outputs the power supply voltage supplied from the first voltage output circuit 4a. Therefore, the output voltage of the first voltage output circuit 4a is supplied to the power supply line VDD of the memory cell array 10 of the semiconductor memory device 1.

As described above, if a variation in the threshold voltages of the transistors constituting the memory cells MC increases, then the operation margin of the write operation and the read operation of the memory cells MC cannot be ensured, in the normal operation mode of the semiconductor memory device. Conventionally, a test step for testing finish threshold voltages of the transistors of the memory cell array 10 by the tester outside the semiconductor integrated circuit system is provided in manufacturing, and the voltage output from the assist circuit is set using the tester outside the semiconductor integrated circuit system. Such a test step causes an increase in a test cost. Since a characteristic of the transistors in the memory cell array 10 could change with time, it is difficult to supply to the memory cells a voltage which ensures a proper operation margin in the normal operation mode, by merely setting the voltages based on the characteristic of the transistors obtained in the test step just after the manufacturing.

In contrast, in the semiconductor integrated circuit system 300 of this embodiment, the power supply voltage and the word line voltage supplied to the memory cell array 10 of the semiconductor memory device 1 during the write operation and the read operation of the semiconductor memory device 1 are changed according to the output of the monitor circuit 2 which is detected within the semiconductor integrated circuit, it is possible to supply to the memory cell a voltage which ensures a proper operation margin in the normal operation mode even after a long-time use, according to a variation in the threshold voltages of the transistors of the memory cell array 10, without increasing a test cost.

In this embodiment, when the semiconductor memory device 1 is in the stand-by mode, the voltage output circuit connected to the power supply line VDDM of the memory cell array 10 of the semiconductor memory device 1 is switched to the second voltage output circuit 4b, and the power supply voltage VDDM of the memory cell array 10 which is supplied from the second voltage output circuit 4b to the semiconductor memory device 1 is changed according to the output of the detecting circuit 3, like Embodiment 1. In this case, since the second voltage output circuit 4b can change the power supply voltage VDDM of the memory cell array 10 in the stand-by mode can be changed according to the finish threshold voltages of the transistors of the memory cells MC, it is possible to supply the power supply voltage which allows the leak current characteristic and the data retaining characteristic to be satisfied well.

Therefore, since the operation margin of the memory cell 10 in the normal operation mode can be ensured, and it is possible to supply the power supply voltage which allows the leak current characteristic and the data retaining characteristic in the stand-by mode, to be satisfied, operation stability and low electric power consumption are achieved. In addition, since the output of the monitor circuit is such that a reference used for changing the voltage supply during the write operation and the read operation is identical to a reference used for changing the voltage supply in the stand-by mode, a size does not increase by addition of the monitor circuit while achieving operation stability and low electric power consumption. The present invention is not limited to this but the voltage supplied to the semiconductor memory device 1 may be changed according to the output of the detecting circuit 3 only when the semiconductor memory device 1 is in the normal operation mode. In this case, one voltage output circuit may be provided.

Although in this embodiment, the assist circuit section 104a is positioned outside the semiconductor memory device 1 and the first voltage output circuit 4a, for example, it may be configured as an internal circuit of the semiconductor memory device 1 or the first voltage output circuit 4a.

### Embodiment 7

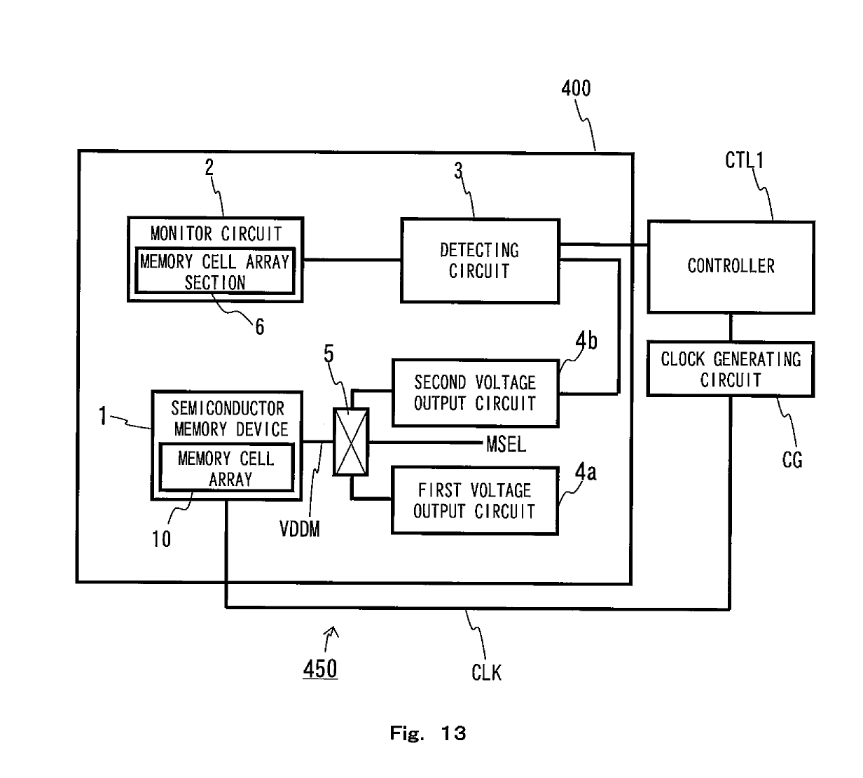

Subsequently, electronic equipment according to Embodiment 7 of the present invention will be described. FIG. 13 is a block diagram showing a schematic configuration of electronic equipment according to Embodiment 7 of the present invention. Electronic equipment 450 of this embodiment incorporates a semiconductor integrated circuit system 400 having a configuration similar to that of Embodiment 1, and includes a clock generating circuit CG for generating a clock signal CLK defining a clock frequency for controlling the semiconductor integrated circuit system 400 and a controller CTL1 for changing a clock frequency of the clock signal CLK generated in the clock generating circuit CG according to the output of the monitor circuit 2. In this embodiment, the electronic equipment 450 includes, for example, a microcomputer, and a CPU in the microcomputer may be used as the controller CTL1. The controller CTL1 may be a main controller for controlling an operation of the electronic equipment 450 or may be a controller provided separately.

As described above, in the semiconductor integrated circuit system, the threshold voltage varies from transistor to transistor manufactured, with a progress of miniaturization of the memory cell array 10. If the threshold voltage of the transistor manufactured is lower than a designed value, its operation speed becomes high, while if the threshold voltage of the transistor manufactured is higher than a designed value, its operation speed becomes low. For this reason, it is desired that a clock frequency for operating the semiconductor integrated circuit be optimized according to a variation in the threshold voltages of the transistors.

In accordance with the electronic equipment 450 of this embodiment, since the controller CTL1 controls the clock generating circuit CG to change the clock frequency of the clock signal CLK according to the finish threshold voltages of the transistors of the memory cells MC, which are monitored by the monitor circuit 2, the memory cells MC of the semiconductor memory device 1 can be regulated so as to operate with an optimal clock frequency CLK within the electronic equipment without using a regulator provided separately.

In accordance with the semiconductor integrated circuit system of this embodiment, the semiconductor memory device 1 can operate with an optimal clock frequency CLK, and a timing margin can be reduced according to a variation, for the memory cells MC in the memory cell array 10 of the semiconductor memory device 1, without increasing a test cost, even when there is a manufacturing variation in the threshold voltages of the transistors or degradation progressing over a log-time use. As a result, a higher-speed operation of the electronic equipment is achieved.

### Embodiment 8

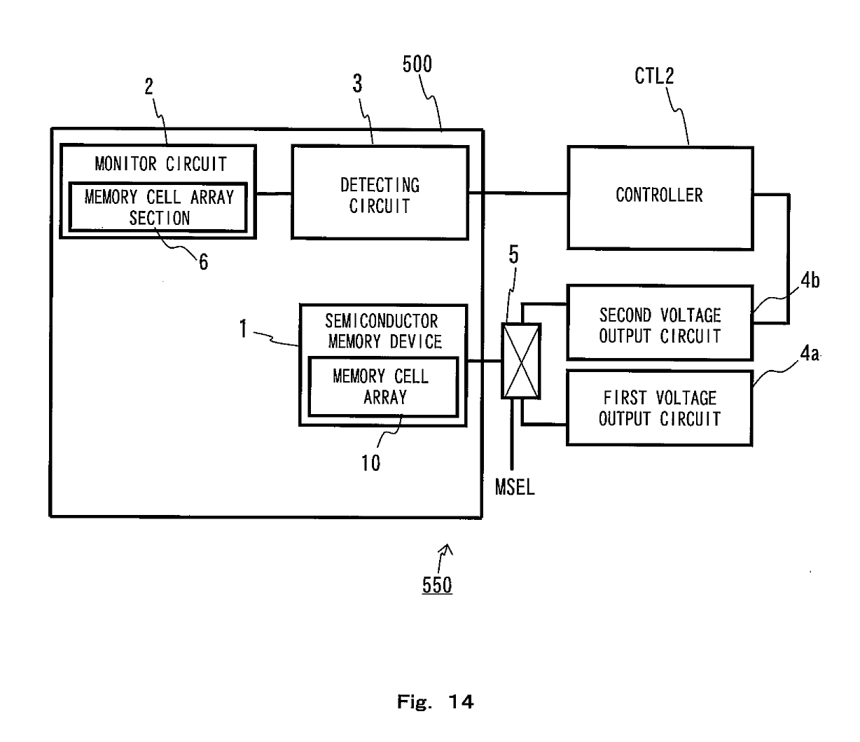

Subsequently, an electronic circuit according to Embodiment 8 of the present invention will be described. FIG. 14 is a block diagram showing a schematic configuration of electronic equipment according to Embodiment 8 of the present invention. Electronic equipment 550 of this embodiment includes a semiconductor integrated circuit system 500 including a semiconductor memory device 1, the monitor circuit 2, and the detecting circuit 3 having configurations identical to those of Embodiment 1, a voltage output circuit connected to the semiconductor memory device 1 to supply a power supply voltage to the semiconductor memory device 1, and a controller CTL2 for changing the output voltage of the voltage output circuit according to the output of the monitor circuit 2. As the voltage output circuit of this embodiment, the first and second voltage output circuits 4a, 4b similar to those mounted in the semiconductor integrated circuit system 100 of Embodiment 1 are provided outside the semiconductor memory device 400. Likewise, the switching circuit 5 is provided outside the semiconductor memory device 400.

In accordance with the electronic equipment 550 having the above configuration, for example, when the power is ON in the electronic equipment 550, the output of the monitor circuit 2 (voltage value associated with the leak current) which is detected by the detecting unit 3 is input to the controller CTL2. The controller CTL2 generates a control signal for changing the voltage output from the second voltage output circuit 4b according to the output of the monitor circuit 2 in a state where the semiconductor memory device 1 is in a stand-by mode. When the semiconductor memory device 1 transitions to the stand-by mode, the mode select signal MSEL is inverted, and therefore the switching circuit 5 connects the second voltage output circuit 4b to the semiconductor memory device 1. In this case, the second voltage output circuit 4b changes the output voltage in accordance with a control signal output from the controller CTL2 and outputs the output voltage to the semiconductor memory device 1.

Thus, since the controller CTL2 changes the voltage supplied from the second voltage output circuit 4b to the semiconductor memory device 1 according to the finish threshold voltages of the transistors of the memory cells MC which are monitored by the monitor circuit 2, it is possible to supply a power supply voltage which allows the leak current characteristic and the data retaining characteristic to be satisfied, to the memory cells MC in the memory cell array 10 of the semiconductor memory device 1, without increasing a test cost, even when there is a manufacturing variation in the threshold voltages of the transistors or degradation progressing over a long-time use.

Numerous modifications and alternative embodiments of the present invention will be apparent to those skilled in the art in view of the foregoing description. Accordingly, the description is to be construed as illustrative only, and is provided for the purpose of teaching those skilled in the art the best mode of carrying out the invention. The details of the structure and/or function may be varied substantially without departing from the spirit of the invention.

For example, two or more of the above described embodiments may be combined, or constituents in the plurality of embodiments may be combined as desired.

A semiconductor integrated circuit system and electronic equipment of the present invention are useful as a semiconductor integrated circuit system and electronic equipment including a semiconductor memory device such as SRAM. In particular, the semiconductor integrated circuit system and electronic equipment of the present invention are useful as a semiconductor integrated circuit system and electronic equipment in which there is a large variation in threshold voltages of transistors constituting memory cells of the semiconductor memory device.

What is claimed is:

1. A semiconductor integrated circuit system comprising:
a semiconductor memory device including a memory cell array having a plurality of memory cells;
a monitor circuit for monitoring characteristics of the memory cells; and
a voltage output circuit connected to the semiconductor memory device to supply a power supply voltage to the semiconductor memory device;
the voltage output circuit being configured to change an output voltage according to an output of the monitor circuit.

2. The semiconductor integrated circuit system according to claim 1,
wherein the voltage output circuit includes a first voltage output circuit and a second voltage output circuit, the first voltage output circuit or the second voltage output circuit is selectively connected to the semiconductor memory device, and the second voltage output circuit is configured to change the output voltage according to the output of the monitor circuit.

3. The semiconductor integrated circuit system according to claim 2,
wherein the second voltage output circuit includes a variable resistor for dividing a voltage to be applied, according to the output of the monitor circuit, and is configured to change the output voltage according to a voltage dividing ratio of the variable resistor.

4. The semiconductor integrated circuit system according to claim 2, comprising:
a power supply switching unit for switching the voltage output circuit to be connected to the semiconductor memory device between the first voltage output circuit and the second voltage output circuit,
wherein the power supply switching unit is configured to permit the power supply voltage to be supplied to the first voltage output circuit and inhibit the power supply voltage from being supplied to the second voltage output circuit in a first mode in which the first voltage output circuit is connected to the semiconductor memory device; and
the power supply switching unit is configured to permit the power supply voltage to be supplied to the second voltage output circuit and inhibit the power supply voltage from being supplied to the first voltage output circuit in a second mode in which the second voltage output circuit is connected to the semiconductor memory device.

5. The semiconductor integrated circuit system according to claim 2,
wherein the output voltage of the second voltage output circuit is set lower than the output voltage of the first voltage output circuit.

6. The semiconductor integrated circuit system according to claim 1,
wherein the monitor circuit includes a memory cell array section including at least one memory cell having a configuration identical to a configuration of the memory cells included in the memory cell array of the semiconductor memory device and a resistor section having one end connected to an outside power supply and an opposite end connected to a power supply line in the memory cell array section, and is configured to output a voltage value at the opposite end side of the resistor section as the characteristics of the memory cells.

7. The semiconductor integrated circuit system according to claim 6, comprising:
a detecting circuit for digitizing the output of the monitor circuit;
wherein the detecting circuit includes one or more comparators for comparing the output voltage of the monitor circuit to one or more reference voltages.

8. The semiconductor integrated circuit system according to claim 7,
wherein the detecting circuit includes one or more holding circuits for holding output data of the one or more comparators;
the comparator is configured to start outputting data in response to a predetermined first signal; and
the holding circuit is configured to, in response to a second signal, take in and hold output data from the comparator, at a time point when the holding circuit receives the second signal sent after a lapse of a predetermined time after the first signal is sent.

9. The semiconductor integrated circuit system according to claim 8,
wherein the second signal is a signal generated from the first signal, and the detecting circuit is configured such that the second signal reaches the holding circuit after a lapse of a predetermined time after the first signal reaches the comparator.

10. The semiconductor integrated circuit system according to claim 8,
wherein the first signal is input to the semiconductor memory device.

11. The semiconductor integrated circuit system according to claim 6, comprising a monitor circuit control unit for switching a state of the memory cell constituting the memory cell array section of the monitor circuit between Low level and High level.

12. The semiconductor integrated circuit system according to claim 11,
wherein the monitor circuit control unit is configured to switch the state of the memory cell constituting the memory cell array section of the monitor circuit between Low level and High level, in accordance with an input signal identical to an input signal to the semiconductor memory device.

13. The semiconductor integrated circuit system according to claim 12,
wherein the input signal identical to the input signal to the semiconductor memory device includes a clock signal defining a clock frequency for controlling the semiconductor memory device and a chip enable signal for switching an operation mode of the memory cells of the semiconductor memory device; and
the monitor circuit control unit is configured to switch the state of the memory cell constituting the memory cell array section between Low level and High level, in synchronization with the clock signal and in accordance with the chip enable signal.

14. The semiconductor integrated circuit system according to claim 6,
wherein the voltage output circuit includes a first voltage output circuit and a second voltage output circuit, the first voltage output circuit or the second voltage output circuit is selectively connected to the semiconductor memory device, and the second voltage output circuit is configured to change the output voltage according to the output of the monitor circuit;
the monitor circuit includes a switch element connected in parallel with the resistor section; and
the switch element is turned ON in a state where the semiconductor memory device is connected to the first voltage output circuit and is turned OFF in a state where the semiconductor memory device is connected to the second voltage output circuit.

15. The semiconductor integrated circuit system according to claim 1, configured to change the power supply voltage of the memory cell array of the semiconductor memory device according to the output of the monitor circuit in a write operation of the semiconductor memory device, and change a word line voltage of the memory cell array of the semiconductor memory device, according to the output of the monitor circuit in a read operation of the semiconductor memory device.

16. The semiconductor integrated circuit system according to claim 15, comprising:
a write assist circuit for changing the power supply voltage of the memory cell array of the semiconductor memory device according to the output of the monitor circuit, in writing of the semiconductor memory device; and
a read assist circuit for changing a power supply voltage of a word line driver for driving the word line voltage of the memory cell array of the semiconductor memory device, according to the output of the monitor circuit, in reading of the semiconductor memory device.

17. Electronic equipment comprising:
the semiconductor integrated circuit system according to claim 1;
a clock generating circuit for generating a clock signal defining a clock frequency for controlling the semiconductor integrated circuit system; and
a controller for changing the clock frequency of the clock signal generated in the clock generating circuit, according to the output of the monitor circuit.

18. Electronic equipment comprising:
a semiconductor integrated circuit system including a semiconductor memory device including a memory cell array having a plurality of memory cells and a monitor circuit for monitoring characteristics of the memory cells;
a voltage output circuit connected to the semiconductor memory device to supply a power supply voltage to the semiconductor memory device; and
a controller for changing the output voltage of the voltage output circuit according to the output of the monitor circuit.
